(19) United States
(12) Patent Application Publication
(10) Pub. No.: US 2026/0321187 A1
(43) Pub. Date: Oct. 15, 2026

(54) Display Substrate and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Zuoji NIU, Beijing (CN); Lili DU, Beijing (CN); Jiaxing CHEN, Beijing (CN); Yi AN, Beijing (CN); Tinghua SHANG, Beijing (CN); Zhongliu YANG, Beijing (CN)

(21) Appl. No.: 18/837,196

(22) PCT Filed: Nov. 28, 2023
(86) PCT No.: PCT/CN2023/134695

§ 371 Date: Aug. 9, 2024

(51) Int. Cl. G09G 3/32; G09G 3/3233

(52) U.S. Cl. CPC G09G 3/32; G09G 3/3233; G09G 2300/0426; G09G 2300/043; G09G 2300/0819; G09G 2330/021; G09G 2330/04

(57) ABSTRACT

A display substrate includes a display area and a peripheral area surrounding the display area. The display area includes at least one segment of an arc-shaped display boundary. The display area includes M rows of sub-pixels provided on a base substrate, and pixel circuits of at least one row of sub-pixels are connected with at least one constant voltage signal line extending in a first direction. N rows of sub-pixels close to the arc-shaped display boundary are arranged in a stepped manner. The peripheral area includes a first bezel area located on a side of the display area in a second direction. The first bezel area includes at least one first area constant voltage power supply line.

### CROSS-REFERENCE TO RELATED APPLICATION

This application is a national stage application of PCT Application No. PCT/CN2023/134695, which is filed on Nov. 28, 2023 and entitled “Display Substrate and Display Apparatus”, the content of which should be regarded as being incorporated herein by reference.

### TECHNICAL FIELD

The present disclosure relates to, but is not limited to, the field of display technologies, in particular to a display substrate and a display apparatus.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc.

### SUMMARY

The following is a summary of subject matters described herein in detail. This summary is not intended to limit the protection scope of claims.

Embodiments of the present disclosure provide a display substrate and a display apparatus.

In one aspect, an embodiment provides a display substrate, including a display area and a peripheral area surrounding the display area. The display area includes at least one segment of an arc-shaped display boundary. The display area includes M rows of sub-pixels provided on a base substrate; at least one row of sub-pixels among the M rows of sub-pixels include a plurality of sub-pixels arranged sequentially in a first direction; at least one sub-pixel among the plurality of sub-pixels includes a pixel circuit and a light emitting element connected with the pixel circuit; and pixel circuits of the at least one row of sub-pixels among the M rows of sub-pixels are electrically connected with at least one constant voltage signal line extending in the first direction. N rows of sub-pixels close to the arc-shaped display boundary are arranged in a stepped manner, where both N and M are positive integers, and N is less than or equal to M. The peripheral area includes a first bezel area located on a side of the display area in a second direction. The second direction intersects with the first direction. The first bezel area includes at least one first area constant voltage power supply line provided on the base substrate. A constant voltage signal line connected by pixel circuits of at least one row of sub-pixels among the N rows of sub-pixels close to the arc-shaped display boundary is connected with the first area constant voltage power supply line of the first bezel area through a first adapter line.

In some exemplary embodiments, a constant voltage signal line connected by pixel circuits of a row of sub-pixels closest to the first bezel area among the N rows of sub-pixels close to the arc-shaped display boundary is connected with the first area constant voltage power supply line of the first bezel area through the first adapter line.

In some exemplary embodiments, the first adapter line includes a first sub-connection line and a second sub-connection line, an extension direction of the first sub-connection line intersects with an extension direction of the second sub-connection line, and the first sub-connection line and the second sub-connection line are connected. The constant voltage signal line connected by the pixel circuits of the row of sub-pixels closest to the first bezel area among the N rows of sub-pixels close to the arc-shaped display boundary is connected with the first sub-connection line, and the second sub-connection line is connected with the first area constant voltage power supply line located in the first bezel area.

In some exemplary embodiments, constant voltage signal lines transmitting a same signal and connected by pixel circuits of K rows of sub-pixels among the N rows of sub-pixels close to the arc-shaped display boundary are connected together and connected with the first area constant voltage power supply line of the first bezel area through the first adapter line, where K is a positive integer less than or equal to N and greater than or equal to 2.

In some exemplary embodiments, K is less than N, and the K rows of sub-pixels are located on a side of remaining rows of sub-pixels of the N rows of sub-pixels close to the first bezel area.

In some exemplary embodiments, the K rows of sub-pixels include seven rows of sub-pixels closest to the first bezel area among the N rows of sub-pixels.

In some exemplary embodiments, the first adapter line includes a first sub-connection line and a second sub-connection line, an extension direction of the first sub-connection line intersects with an extension direction of the second sub-connection line, and the first sub-connection line and the second sub-connection line are connected. Constant voltage signal lines transmitting a same signal and connected by pixel circuits of adjacent rows of sub-pixels among the K rows of sub-pixels are electrically connected through a series connection line, a constant voltage signal line connected by pixel circuits of a row of sub-pixels closest to the first bezel area among the K rows of sub-pixels is connected with the first sub-connection line, and the second sub-connection line is connected with the first area constant voltage power supply line located in the first bezel area.

In some exemplary embodiments, series connection lines connected by the constant voltage signal lines connected by the pixel circuits of adjacent rows of sub-pixels among the K rows of sub-pixels extend in a stepped shape formed by the adjacent rows of sub-pixels.

In some exemplary embodiments, the series connection line is located on a side of the constant voltage signal line connected therewith away from the base substrate.

In some exemplary embodiments, the first sub-connection line and the second sub-connection line are located on a side of the first area constant voltage power supply line connected therewith away from the base substrate. The second sub-connection line is located on a side of the first sub-connection line away from the base substrate, or the second sub-connection line and the first sub-connection line are of an interconnected integral structure.

In some exemplary embodiments, the first bezel area further includes a plurality of electrostatic discharge circuits, each of which is connected with a signal line and configured to discharge static electricity from the signal line connected therewith. The second sub-connection line is located on a side of the plurality of electrostatic discharge circuits away from an edge of the display substrate in the first direction.

In some exemplary implementations, the peripheral area further includes a second bezel area located on at least one side of the display area in the first direction. The second bezel area includes at least one second area constant voltage power supply line provided on the base substrate. The second area constant voltage power supply line is connected with the first area constant voltage power supply line. The constant voltage signal line connected by the pixel circuits of the at least one row of sub-pixels among the M rows of sub-pixels is electrically connected with the second area constant voltage power supply line through a second adapter line.

In some exemplary embodiments, the second bezel area further includes at least one gate drive circuit provide on the base substrate. The second area constant voltage power supply line is located on a side of the gate drive circuit close to the display area.

In some exemplary embodiments, an orthographic projection of the second area constant voltage power supply line on the base substrate is at least partially overlapped with an orthographic projection of the gate drive circuit on the base substrate.

In some exemplary embodiments, a plurality of constant voltage signal lines connected by pixel circuits of each row of sub-pixel circuits include a first initial signal line, a second initial signal line, and a third initial signal line. The pixel circuit at least includes a drive transistor, a first reset transistor, a second reset transistor, and a third reset transistor. A gate of the drive transistor is connected with a first node, a first electrode of the drive transistor is connected with a second node, and a second electrode of the drive transistor is connected with a third node. The first reset transistor is connected with the third node and the first initial signal line, and configured to reset the third node using a first initial signal provided by the first initial signal line. The second reset transistor is connected with the second initial signal line and an anode of the light emitting element, and configured to reset the anode of the light emitting element using a second initial signal provided by the second initial signal line. The third reset transistor is connected with the second node and the third initial signal line, and configured to reset the second node using a third initial signal provided by the third initial signal line. A plurality of first area constant voltage power supply lines provided in the first bezel area include a first initial power supply line, a second initial power supply line and a third initial power supply line. The first initial signal line connected by the pixel circuits of the at least one row of sub-pixels among the N rows of sub-pixels close to the arc-shaped display boundary is connected with the first initial power supply line of the first bezel area. The second initial signal line connected by the pixel circuits of the at least one row of sub-pixels among the N rows of sub-pixels close to the arc-shaped display boundary is connected with the second initial power supply line of the first bezel area. The third initial signal line connected by the pixel circuits of the at least one row of sub-pixels among the N rows of sub-pixels close to the arc-shaped display boundary is connected with the third initial power supply line of the first bezel area. The first initial power supply line, the second initial power supply line, and the third initial power supply line are sequentially provided in a direction close to the display area.

In some exemplary embodiments, the peripheral area further includes a second bezel area located on a side of the display area in the first direction, and the second bezel area is in communication with the first bezel area. The second bezel area includes a plurality of second area constant voltage power supply lines, and the plurality of second area constant voltage power supply lines include a fourth initial power supply line, a fifth initial power supply line and a sixth initial power supply line. The fourth initial power supply line is connected with the first initial power supply line, the fifth initial power supply line is connected with the second initial power supply line, and the sixth initial power supply line is connected with the third initial power supply line. The fourth initial power supply line, the fifth initial power supply line, and the sixth initial power supply line are sequentially provided in the direction close to the display area.

In some exemplary embodiments, in a direction perpendicular to the display substrate, the display substrate includes a first semiconductor layer, a first conductive layer, a second conductive layer, a second semiconductor layer, a third conductive layer, a fourth conductive layer, and a fifth conductive layer provided on the base substrate. The constant voltage signal line is located on the third conductive layer. The at least one first area constant voltage power supply line is located on the first conductive layer, or on the second conductive layer, or is a double-layer trace located on the first conductive layer and the second conductive layer.

In another aspect, an embodiment provides a display apparatus, including the aforementioned display substrate.

In another aspect, an embodiment provides a display substrate, including a display area and a peripheral area surrounding the display area. The display area includes at least one segment of an arc-shaped display boundary. The display area includes M rows of sub-pixels provided on a base substrate; at least one row of sub-pixels among the M rows of sub-pixels include a plurality of sub-pixels arranged sequentially in a first direction; at least one sub-pixel among the plurality of sub-pixels includes a pixel circuit and a light emitting element connected with the pixel circuit; and pixel circuits of the at least one row of sub-pixels among the M rows of sub-pixels are connected with at least one constant voltage signal line extending in the first direction. N rows of sub-pixels close to the arc-shaped display boundary are arranged in a stepped manner, where both N and M are positive integers, and N is less than or equal to M. The peripheral area includes a first bezel area located on a side of the display area in a second direction and a first corner area located at a perimeter of the arc-shaped display boundary, and the first bezel area is in communication with the first corner area. The second direction intersects with the first direction. The first bezel area includes at least one first area constant voltage power supply line provided on the base substrate. A constant voltage signal line connected by pixel circuits of at least one row of sub-pixels among the N rows of sub-pixels close to the arc-shaped display boundary is connected with the first area constant voltage power supply line of the first bezel area through a first adapter line. A portion of the first adapter line is located in the first corner area.

In some exemplary embodiments, the first adapter line includes a first sub-connection line and a second sub-connection line, an extension direction of the first sub-connection line intersects with an extension direction of the second sub-connection line, and the first sub-connection line and the second sub-connection line are connected. The first sub-connection line is connected with the constant voltage signal line connected by the pixel circuits of the at least one row of sub-pixels among the N rows of sub-pixels close to the arc-shaped display boundary, and the second sub-connection line is connected with the first area constant voltage power supply line. A connection position of the first sub-connection line and the second sub-connection line is located in the first corner area.

In some exemplary embodiments, the peripheral area further includes at least one second area constant voltage power supply line extending to the first corner area and connected with the first area constant voltage power supply line through the second sub-connection line.

In some exemplary embodiments, the second area constant voltage power supply line and the second sub-connection line connected therewith are of an interconnected integral structure.

In some exemplary embodiments, the first corner area further includes a plurality of cascaded drive units provided on the base substrate, the second area constant voltage power supply line is located on a side of the plurality of cascaded drive units close to the display area, and the second sub-connection line is located on a side of the plurality of drive units close to the first area constant voltage power supply line in the first direction.

In some exemplary embodiments, the drive units are connected with a gate line connected by at least one row of sub-pixels through a drive connection line, and the drive connection line is located on a side of the first sub-connection line close to the display area in the second direction.

Other aspects of the present disclosure may be comprehended after the drawings and the detailed descriptions are read and understood.

### BRIEF DESCRIPTION OF DRAWINGS

Accompanying drawings are used for providing an understanding of technical solutions of the present application and form a part of the specification, are used for explaining the technical solutions of the present application together with embodiments of the present application, and do not constitute a limitation on the technical solutions of the present application.

FIG. 1 is a schematic diagram of a display substrate according to at least one embodiment of the present disclosure.

FIG. 2 is an equivalent circuit diagram of a pixel circuit according to at least one embodiment of the present disclosure.

FIG. 3 is a working timing diagram of the pixel circuit provided in FIG. 2.

FIG. 4A is a schematic diagram of a partial structure of area C1 in FIG. 1.

FIG. 4B is a schematic diagram of partial line connection in area C3 of FIG. 4A.

FIG. 4C is a schematic diagram of partial line connection in area C4 of FIG. 4A.

FIG. 5 is an equivalent circuit diagram of drive units of a first scan gate drive circuit according to at least one embodiment of the present disclosure.

FIG. 6 is a working timing diagram of the drive units of the first scan gate drive circuit shown in FIG. 5.

FIG. 7 is an equivalent circuit diagram of an electrostatic discharge circuit according to at least one embodiment of the present disclosure.

FIG. 8 is a schematic diagram of a partial structure of area C2 in FIG. 4A.

FIG. 9A is a schematic plan view of the area C2 in FIG. 8 after a third trace layer is formed.

FIG. 9B is a schematic plan view of the area C2 in FIG. 8 after a second trace layer is formed.

FIG. 9C is a schematic plan view of the area C2 in FIG. 8 after a first trace layer is formed.

FIG. 10A is a partial schematic diagram of area C1 after a first semiconductor layer is formed.

FIG. 10B is a partial schematic diagram of a display area after a first semiconductor layer is formed.

FIG. 10C is a partial schematic diagram of a first corner area after a first semiconductor layer is formed.

FIG. 11A is a partial schematic diagram of a first conductive layer of area C1.

FIG. 11B is a partial schematic diagram of a display area after a first conductive layer is formed.

FIG. 11C is a partial schematic diagram of a first corner area after a first conductive layer is formed.

FIG. 12A is a partial schematic diagram of a second conductive layer of area C1.

FIG. 12B is a partial schematic diagram of a display area after a second conductive layer is formed.

FIG. 12C is a partial schematic diagram of a first corner area after a second conductive layer is formed.

FIG. 13A is a partial schematic diagram of a second semiconductor layer of area C1.

FIG. 13B is a partial schematic diagram of a display area after a second semiconductor layer is formed.

FIG. 14A is a partial schematic diagram of a third conductive layer of area C1.

FIG. 14B is a partial schematic diagram of a display area after a third conductive layer is formed.

FIG. 14C is a partial schematic diagram of a first corner area after a third conductive layer is formed.

FIG. 15A is a partial schematic diagram of a display area after a fifth insulating layer is formed.

FIG. 15B is a partial schematic diagram of a first corner area after a fifth insulating layer is formed.

FIG. 16A is a partial schematic diagram of a fourth conductive layer of area C1.

FIG. 16B is a partial schematic diagram of a display area after a fourth conductive layer is formed.

FIG. 16C is a partial schematic diagram of a first corner area after a fourth conductive layer is formed.

FIG. 17A is a partial schematic diagram of a display area after a seventh insulating layer is formed.

FIG. 17B is a partial schematic diagram of a first corner area after a seventh insulating layer is formed.

FIG. 18A is a partial schematic diagram of area C1 after a fifth conductive layer is formed.

FIG. 18B is a schematic diagram of the fifth conductive layer in FIG. 18A.

FIG. 18C is a partial schematic diagram of a display area after a fifth conductive layer is formed.

FIG. 18D is a partial schematic diagram of a first corner area after a fifth conductive layer is formed.

FIG. 19 is a partial schematic diagram of a display area after an eighth insulating layer is formed.

FIG. 20A is a partial schematic diagram of a display area after a sixth conductive layer is formed.

FIG. 20B is a schematic diagram of the sixth conductive layer in FIG. 20A.

FIG. 21A is a schematic diagram of another partial structure of area C1 in FIG. 1.

FIG. 21B is a schematic diagram of partial line connection in area C5 of FIG. 21A.

FIG. 21C is a schematic diagram of partial line connection in area C6 of FIG. 21A.

FIG. 22 is a partial schematic diagram of a display area according to at least one embodiment of the present disclosure.

FIG. 23A is a schematic diagram of a display area after a third conductive layer is formed in FIG. 22.

FIG. 23B is a schematic diagram of the fourth conductive layer in FIG. 22.

FIG. 23C is a schematic diagram of the fifth conductive layer in FIG. 22.

FIG. 24 is a schematic diagram of another partial structure of area C1 in FIG. 1.

FIG. 25 is a schematic diagram of a display apparatus according to at least one embodiment of the present disclosure.

### DETAILED DESCRIPTION

The embodiments of the present disclosure will be described below with reference to the drawings in detail. Implementation modes may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined explicitly, terms “mount”, “mutually connect”, “connect”, and “couple” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate, a drain, and a source. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, a first electrode may be a drain electrode and a second electrode may be a source electrode, or, a first electrode may be a source electrode and a second electrode may be a drain electrode. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification. In addition, the gate may also be referred to as a control electrode.

In the specification, “parallel” refers to a state in which an angle formed by two straight lines is −10° or more and 100 or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 950 or less.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, the same may include the cases of exactly the same and substantially the same. “Substantially the same” refers to a case where numerical values differ within 10%.

In the present disclosure, “A extends in a B direction” means that A may include a main body portion and a secondary portion connected with the main body portion, the main body portion is a line, a line segment, or a strip-shaped body, the main body portion extends in the B direction, and a length of the main body portion extending in the B direction is greater than a length of the secondary portion extending in another direction. “A extends in the B direction” in the present disclosure means “the main portion of A extends in the B direction”.

With the increasing attention to a narrow bezel design, display devices (such as mobile display devices such as mobile phones) have higher and higher requirements for screen bezel size. By reducing a proportion of the bezel, black edges of a display may be reduced. On the one hand, it may make the display device (such as a mobile phone) look more fashionable, and on the other hand, it may effectively alleviate the problems caused by large-screen display devices such as inconvenient holding, thereby enabling users to operate more easily. In order to meet the narrow bezel design, a Corner size of the display device is limited. When a corner space is less than 1.0 millimeter (mm), a line connection space in the corner will be greatly constrained, making it difficult for a trace space to reach the control range. For example, when the corner space is less than or equal to 0.95 mm, in order to ensure the line width of the low potential (VSS) power supply line in the surrounding area, a cut-off area of the gate drive circuit is usually higher than the last row of sub-pixels, which severely restricts the line connection space of the last few rows of sub-pixels, making it impossible to ensure normal connection and signal transmission.

An embodiment provides a display substrate and a display apparatus, which may improve an arrangement space for line connection in a peripheral area (such as a corner area), thereby enabling normal signal transmission and facilitating narrow bezel design.

An embodiment provides a display substrate, including a display area and a peripheral area surrounding the display area. The display area includes at least one segment of an arc-shaped display boundary. The display area includes M rows of sub-pixels provided on a base substrate; at least one row of sub-pixels among the M rows of sub-pixels include a plurality of sub-pixels arranged sequentially in a first direction; at least one sub-pixel includes a pixel circuit and a light emitting element connected with the pixel circuit; and pixel circuits of the at least one row of sub-pixels among the M rows of sub-pixels are connected with at least one constant voltage signal line extending in the first direction. N rows of sub-pixels close to the arc-shaped display boundary are arranged in a stepped manner, where both N and M are positive integers, and N is less than or equal to M. The peripheral area includes a first bezel area located on a side of the display area in a second direction. The first direction intersects with the second direction. For example, the first direction may be perpendicular to the second direction. The first bezel area includes at least one first area constant voltage power supply line provided on the base substrate. A constant voltage signal line connected by pixel circuits of at least one row of sub-pixels among the N rows of sub-pixels close to the arc-shaped display boundary is connected with the first area constant voltage power supply line of the first bezel area through a first adapter line.

According to the display substrate provided by the present embodiment, the constant voltage signal line connected by the pixel circuits of the at least one row of sub-pixels among the N rows of sub-pixels close to the arc-shaped display boundary is provided to be connected with the first area constant voltage power supply line of the first bezel area, which may reduce a quantity of traces in a perimeter area of the arc-shaped display boundary and ensure normal line connection of a plurality of rows of sub-pixels close to the arc-shaped display boundary, thereby facilitating the narrow bezel design.

In some exemplary embodiments, the at least one constant voltage signal line connected by pixel circuits of a row of sub-pixels closest to the first bezel area among the N rows of sub-pixels close to the arc-shaped display boundary may be connected with the at least one first area constant voltage power supply line of the first bezel area through the first adapter line. In the present example, the constant voltage signal line connected by the pixel circuits of the row of sub-pixels closest to the first bezel area among the N rows of sub-pixels close to the arc-shaped display boundary is provided to be connected with the first area constant voltage power supply line of the first bezel area, which reduces a quantity of traces in a perimeter area of the arc-shaped display boundary while ensuring normal signal transmission of a plurality of rows of sub-pixels close to the arc-shaped display boundary, thereby facilitating the narrow bezel design.

In some exemplary embodiments, the first adapter line may include a first sub-connection line and a second sub-connection line, an extension direction of the first sub-connection line intersects with an extension direction of the second sub-connection line, and the first sub-connection line and the second sub-connection line are connected. The constant voltage signal line connected by the pixel circuits of the row of sub-pixels closest to the first bezel area among the N rows of sub-pixels close to the arc-shaped display boundary is connected with the first sub-connection line, and the second sub-connection line is connected with the first area constant voltage power supply line located in the first bezel area. The present example realizes connection between the constant voltage signal line and the first area constant voltage power supply line through sequential transfer of the first sub-connection line and the second sub-connection line, which is conducive to saving the trace space. In some examples, the first sub-connection line may be a trace extending in a single direction, for example, may extend in a first direction. Alternatively, the first sub-connection line may not be a trace extending in a single direction, for example, the first sub-connection line may be formed by connecting line segments extending in a plurality of different directions, and the plurality of different directions may include the first direction and other directions intersecting with the first direction. In some examples, the second sub-connection line may be a trace extending in a single direction, for example, may extend in a second direction, or a third direction, or a fourth direction. Alternatively, the second sub-connection line may not be a trace extending in a single direction, for example, the second sub-connection line may be formed by connecting line segments extending in a plurality of different directions, and the plurality of different directions may include the second direction and other directions intersecting with the second direction, or the plurality of different directions may include the third direction and other directions intersecting with the third direction. The present embodiment is not limited thereto.

In some exemplary embodiments, constant voltage signal lines transmitting a same signal and connected by pixel circuits of K rows of sub-pixels among the N rows of sub-pixels close to the arc-shaped display boundary are connected in series and connected with the first area constant voltage power supply line of the first bezel area through the first adapter line, where K is a positive integer less than or equal to N and greater than or equal to 2. For example, K may be less than N, or K may be equal to N. In some examples, the first adapter line may include a first sub-connection line extending in at least the first direction and a second sub-connection line extending in at least the second direction, and the first sub-connection line and the second sub-connection line are connected. Constant voltage signal lines transmitting a same signal and connected by pixel circuits of adjacent rows of sub-pixels among the K rows of sub-pixels are electrically connected through a series connection line, a constant voltage signal line connected by pixel circuits of a row of sub-pixels closest to the first bezel area among the K rows of sub-pixels is connected with the first sub-connection line, and the second sub-connection line is connected with the first area constant voltage power supply line located in the first bezel area. In the present example, by connecting the constant voltage signal lines transmitting the same signal and connected by adjacent sub-pixels in series, a quantity of traces in a perimeter area of the arc-shaped display boundary may be reduced, thereby facilitating the narrow bezel design.

In some exemplary implementations, the peripheral area may further include a second bezel area located on at least one side of the display area in the first direction. The second bezel area includes at least one second area constant voltage power supply line provided on the base substrate. The second area constant voltage power supply line is connected with the first area constant voltage power supply line. The constant voltage signal line connected by the pixel circuits of the at least one row of sub-pixels among the M rows of sub-pixels is electrically connected with the second area constant voltage power supply line through a second adapter line. For example, the second adapter line may be formed by connecting line segments extending in the first direction and line segments extending in other directions intersecting with the first direction.

In some exemplary embodiments, a plurality of constant voltage signal lines connected by pixel circuits of each row of sub-pixel circuits include a first initial signal line, a second initial signal line, and a third initial signal line. The pixel circuit may at least include a drive transistor, a first reset transistor, a second reset transistor, and a third reset transistor. A gate of the drive transistor is connected with a first node, a first electrode of the drive transistor is connected with a second node, and a second electrode of the drive transistor is connected with a third node. The first reset transistor is connected with the third node and the first initial signal line, and configured to reset the third node using a first initial signal provided by the first initial signal line. The second reset transistor is connected with the second initial signal line and an anode of the light emitting element, and configured to reset the anode of the light emitting element using a second initial signal provided by the second initial signal line. The third reset transistor is connected with the second node and the third initial signal line, and configured to reset the second node using a third initial signal provided by the third initial signal line. A plurality of first area constant voltage power supply lines provided in the first bezel area include a first initial power supply line, a second initial power supply line and a third initial power supply line. The first initial signal line connected by the pixel circuits of the at least one row of sub-pixels among the N rows of sub-pixels close to the arc-shaped display boundary is connected with the first initial power supply line of the first bezel area. The second initial signal line connected by the pixel circuits of the at least one row of sub-pixels among the N rows of sub-pixels close to the arc-shaped display boundary is connected with the second initial power supply line of the first bezel area. The third initial signal line connected by the pixel circuits of the at least one row of sub-pixels among the N rows of sub-pixels close to the arc-shaped display boundary is connected with the third initial power supply line of the first bezel area. The first initial power supply line, the second initial power supply line, and the third initial power supply line may be sequentially provided in a direction close to the display area. In the present example, by providing the initial signal line connected by the pixel circuits to be connected with the corresponding initial power supply line in the first bezel area, a quantity of traces in a perimeter area of the arc-shaped display boundary may be reduced while ensuring normal signal transmission, thereby facilitating the narrow bezel design.

Solutions of the embodiments will be described below through some examples.

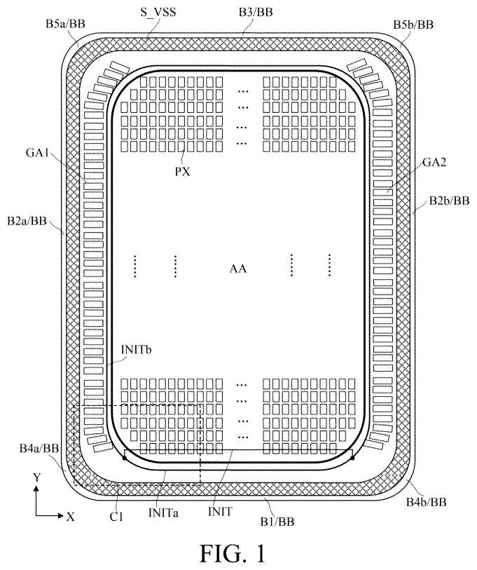

FIG. 1 is a schematic diagram of a display substrate according to at least one embodiment of the present disclosure. In some examples, as shown in FIG. 1, the display substrate may include a display area AA, and a peripheral area BB surrounding the display area AA. The display area AA may at least include one segment of an arc-shaped display boundary. In some examples, the display area AA may include a plurality of straight display boundaries and a plurality of arc-shaped display boundaries, and the arc-shaped display boundaries may be connected with the straight display boundaries. For example, as shown in FIG. 1, the display area AA may be substantially a rounded rectangle, and the display area AA may include a first edge (lower edge) and a second edge (upper edge) provided opposite to each other in a second direction Y, and a third edge (left edge) and a fourth edge (right edge) provided opposite to each other in a first direction X. The first edge and the second edge may be straight display boundaries parallel to each other, the third edge and the fourth edge may be straight display boundaries parallel to each other, and adjacent straight display boundaries may be connected through an arc-shaped display boundary. In some other examples, the display area AA may include only a plurality of arc-shaped display boundaries. For example, the display area AA may be a circle or an oval formed by sequentially connecting a plurality of arc-shaped display boundaries. However, the present embodiment is not limited thereto.

In some examples, the display area AA may include M rows of sub-pixels PX. At least one row of sub-pixels PX among the M rows of sub-pixels may include a plurality of sub-pixels arranged sequentially in the first direction X. For example, each row of sub-pixels PX may include a plurality of sub-pixels arranged sequentially in the first direction X. N rows of sub-pixels close to the arc-shaped display boundary may be arranged in a stepped manner. For example, quantities of sub-pixels of the N rows of sub-pixels adjacent to a lower bezel area and adjacent to the arc-shaped display boundary may be sequentially increased in the second direction Y. Herein, N and M may both be positive integers, and N may be less than or equal to M. In some examples, stepped arrangement may be a 90 degree stepped arrangement, or may be stepped arrangement at other angles, which may be determined according to a layout of the display substrate. In some other examples, edges of the N rows of sub-pixels close to the arc-shaped display boundary may be arranged in a wavy manner.

In some examples, at least one sub-pixel may include a pixel circuit and a light emitting element electrically connected with the pixel circuit. The pixel circuit may be configured to drive the light emitting element connected therewith. For example, the pixel circuit may be configured to provide a drive current to drive the light emitting element connected therewith to emit light. The pixel circuit may include a plurality of transistors and at least one capacitor. For example, the pixel circuit may be a circuit of a 3T1C, 4T1C, 5T1C, 5T2C, 6T1C, 7T1C, 8T1C or 8T2C structure. Herein, in the above circuit structure, T refers to a thin film transistor, C refers to a capacitor, a number before T represents a quantity of thin film transistors in the circuit, and a number before C represents a quantity of capacitors in the circuit.

In some examples, the light emitting element may be any of a Light Emitting Diode (LED), an Organic Light Emitting Diode (OLED), a Quantum dot Light Emitting Diode (QLED), a micro LED (including: mini-LED or micro-LED), and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected with a corresponding pixel circuit. However, the present embodiment is not limited thereto.

In some examples, one pixel unit of the display area AA may include three sub-pixels. For example, the three sub-pixels may be a red sub-pixel, a green sub-pixel, and a blue sub-pixel, respectively. However, the present embodiment is not limited thereto. In some other examples, one pixel unit of the display area AA may include four sub-pixels, and the fourth sub-pixels may include two green sub-pixels, one red sub-pixel, and one blue sub-pixel. In some other examples, one pixel unit may include four sub-pixels, which may be a red sub-pixel, a green sub-pixel, a blue sub-pixel, and a white sub-pixel respectively.

In some examples, a shape of the light emitting element may be a rectangle, a rhombus, a pentagon, or a hexagon. When one pixel unit includes three sub-pixels, light emitting elements of the three sub-pixels may be arranged side by side horizontally, side by side vertically, or in a delta-shaped arrangement. When one pixel unit includes four sub-pixels, light emitting elements of the four sub-pixels may be arranged side by side horizontally, side by side vertically, or in a square arrangement. However, the present embodiment is not limited thereto.

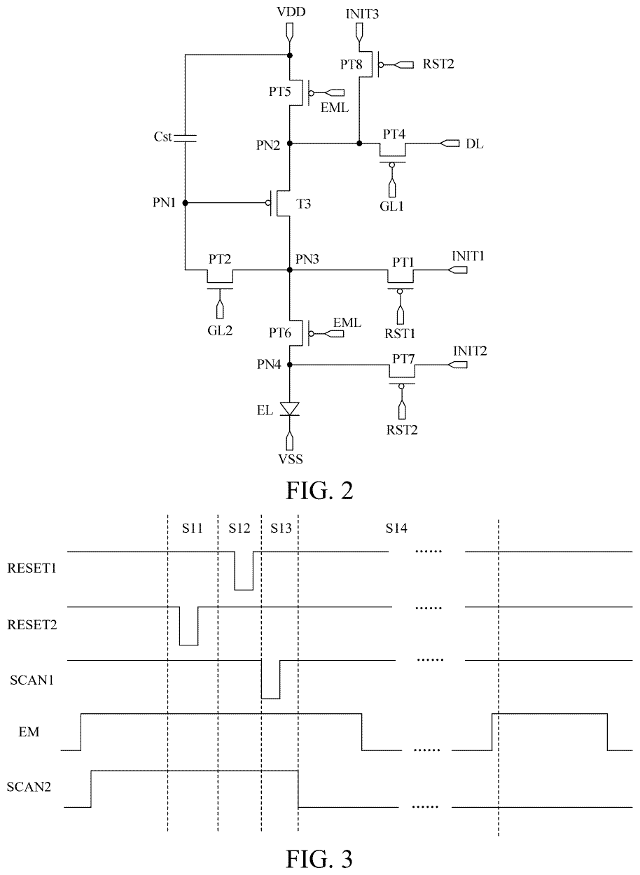

FIG. 2 is an equivalent circuit diagram of a pixel circuit according to at least one embodiment of the present disclosure. The pixel circuit of this example is described by taking an 8T1C structure as an example. In some examples, as shown in FIG. 2, the pixel circuit of the present example may include eight transistors (i.e., a first pixel transistor PT1 to an eighth pixel transistor PT8) and one storage capacitor Cst. The first pixel transistor PT1 may also be referred to as a first reset transistor, the second pixel transistor PT2 may also be referred to as a threshold compensation transistor, the third pixel transistor PT3 may also be referred to as a drive transistor, the fourth pixel transistor PT4 may also be referred to as a data writing transistor, the fifth pixel transistor PT5 may also be referred to as a first light emitting control transistor, the sixth pixel transistor PT6 may also be referred to as a second light emitting control transistor, the seventh pixel transistor PT7 may also be referred to as a second reset transistor, and the eighth pixel transistor PT8 may also be referred to as a third reset transistor. The light emitting element EL may include an anode, a cathode and an organic emitting layer provided between the anode and the cathode.

In some examples, the first pixel transistor PT1, and the third pixel transistor PT3 to the eighth pixel transistor PT8 may be first type transistors, which may be, for example, P-type transistors, and the second pixel transistor PT2 may be a second type transistor, which may be, for example, an N-type transistor. However, the present embodiment is not limited thereto. For example, the plurality of transistors of the pixel circuit may all be P-type transistors, or may all be N-type transistors. Using the same type of transistor in the pixel circuit may simplify the process flow, reduce the process difficulty of the display substrate, and improve the yield of a product.

In some examples, for first type transistors (including, for example, the first pixel transistor PT1 and the third pixel transistor PT3 to the eighth pixel transistor PT8) of the pixel circuit, a low temperature poly silicon thin film transistor may be adopted, and for a second type transistor (including, for example, the second pixel transistor PT2) of the pixel circuit, an oxide thin film transistor may be adopted. Low Temperature Poly Silicon (LTPS) is used for an active layer of a low temperature poly silicon thin film transistor and an oxide semiconductor (Oxide) is used for an active layer of an oxide thin film transistor. A low temperature poly silicon thin film transistor has advantages such as a high mobility rate and fast charging, and an oxide thin film transistor has advantages such as a low leakage current. The low temperature poly silicon thin film transistor and the oxide thin film transistor are integrated on one display substrate to form a Low Temperature Polycrystalline Oxide (LTPS+Oxide) display substrate, and advantages of both the low temperature poly silicon thin film transistor and the oxide thin film transistor may be utilized, which may achieve low-frequency drive, reduce power consumption, and improve display quality.

In some examples, as shown in FIG. 2, the pixel circuit may be electrically connected with the first scan line GL1, the second scan line GL2, the data line DL, the first power supply line VDD, the second power supply line VSS, the light emitting control line EML, the first initial signal line INIT1, the second initial signal line INIT2, the third initial signal line INIT3, the first reset control line RST1, and the second reset control line RST2. The first power supply line VDD may be configured to provide a constant first voltage signal Vdd to the pixel circuit, the second power supply line VSS may be configured to provide a constant second voltage signal Vss to the pixel circuit, and the first voltage signal Vdd may be greater than the second voltage signal Vss. The first scan line GL1 may be configured to provide a first scan signal SCAN1 to the pixel circuit. The second scan line GL2 may be configured to provide a second scan signal SCAN2 to the pixel circuit. The data line DL may be configured to provide a data signal to the pixel circuit. The light emitting control line EML may be configured to provide a light emitting control signal EM to the pixel circuit. The first reset control line RST1 may be configured to provide a first reset control signal RESET1 to the pixel circuit. The second reset control line may be configured to provide a second reset control signal RESET2 to the pixel circuit.

In some examples, as shown in FIG. 2, a gate of the third pixel transistor PT3 is electrically connected with a first node PN1, a first electrode of the third pixel transistor PT3 is electrically connected with a second node PN2, and a second electrode of the third pixel transistor PT3 is electrically connected with a third node PN3. A gate of the fourth pixel transistor PT4 is electrically connected with the first scan line GL1, a first electrode of the fourth pixel transistor PT4 is electrically connected with the data line DL, and a second electrode of the fourth pixel transistor PT4 is electrically connected with the second node PN2. A gate of the second pixel transistor PT2 is connected with the second scan signal line GL2, a second electrode of the second pixel transistor PT2 is electrically connected with the first node PN1, and a first electrode of the second pixel transistor PT2 is electrically connected with the third node PN3. A gate of the fifth pixel transistor PT5 is electrically connected with the light emitting control line EML, a first electrode of the fifth pixel transistor PT5 is electrically connected with the first power supply line VDD, and a second electrode of the fifth pixel transistor PT5 is electrically connected with the second node PN2. A gate of the sixth pixel transistor PT6 is electrically connected with the light emitting control line EML, a first electrode of the sixth pixel transistor PT6 is electrically connected with the third node PN3, and a second electrode of the sixth pixel transistor PT6 is electrically connected with a fourth node PN4. A gate of the first pixel transistor PT1 is electrically connected with the first reset control line RST1, a first electrode of the first pixel transistor PT1 is electrically connected with the first initial signal line INIT1, and a second electrode of the first pixel transistor PT1 is electrically connected with the third node PN3. The first pixel transistor PT1 may be configured to reset the third node PN3. A gate of the seventh pixel transistor PT7 is electrically connected with the second reset control line RST2, a first electrode of the seventh pixel transistor PT7 is electrically connected with the second initial signal line INIT2, and a second electrode of the seventh pixel transistor PT7 is electrically connected with the fourth node PN4. The seventh pixel transistor PT7 may be configured to reset the fourth node PN4. A gate of the eighth pixel transistor PT8 is electrically connected with the second reset control line RST2, a first electrode of the eighth pixel transistor PT8 is electrically connected with the third initial signal line INIT3, and a second electrode of the eighth pixel transistor PT8 is electrically connected with the second node PN2. The eighth pixel transistor PT8 may be configured to reset the second node PN2. A first electrode of the storage capacitor Cst is electrically connected with the first node PN1, and a second electrode of the storage capacitor Cst is electrically connected with the first power supply line VDD.

In the example, the first node PN1 is a connection point of the storage capacitor Cst, the second pixel transistor PT2, and the third pixel transistor PT3, the second node PN2 is a connection point of the fifth pixel transistor PT5, the fourth pixel transistor PT4, the eighth pixel transistor PT8, and the third pixel transistor PT3, the third node PN3 is a connection point of the first pixel transistor PT1, the third pixel transistor PT3, the second pixel transistor PT2, and the sixth pixel transistor PT6, and the fourth node PN4 is a connection point of the sixth pixel transistor PT6, the seventh pixel transistor PT7, and the light emitting element EL.

FIG. 3 is a working timing diagram of the pixel circuit provided in FIG. 2. A working process of the pixel circuit shown in FIG. 2 will be described below with reference to FIG. 3. The first pixel transistor PT1, and the third pixel transistor PT3 to the eighth pixel transistor PT8 of the pixel circuit are P-type transistors, and the second pixel transistor PT2 is an N-type transistor.

In some examples, as shown in FIGS. 2 and 3, during one frame of display period, the working process of the pixel circuit may at least include a first stage S11, a second stage S12, a third stage S13, and a fourth stage S14.

The first stage S11 is referred to as a first reset stage. The second reset control signal RESET2 provided by the second reset control line RST2 is a low level signal to turn on the seventh pixel transistor PT7 and the eighth pixel transistor PT8, and the second scan signal SCAN2 provided by the second scan line GL2 is a high level signal to turn on the second pixel transistor PT2. The eighth pixel transistor PT8 is turned on so that the third initial signal provided by the third initial signal line INIT3 is provided to the second node PN2. The seventh pixel transistor PT7 is turned on so that the second initial signal provided by the second initial signal line INIT2 is provided to the fourth node PN4 to initialize the fourth node PN4. The first scan signal SCAN1 provided by the first scan line GL1 is a high level signal, the first reset control signal RESET1 provided by the first reset control line RST1 is a high level signal, and the light emitting control signal EM provided by the light emitting control line EML is a high level signal, so that the fourth pixel transistor PT4, the first pixel transistor PT1, the fifth pixel transistor PT5 and the sixth pixel transistor PT6 are turned off. In this stage, the light emitting element EL does not emit light.

The second stage S12 is referred to as a second reset stage. The first reset control signal RESET1 provided by the first reset control line RST1 is a low level signal, and the first pixel transistor PT1 is turned on. The second scan signal SCAN2 provided by the second scan line GL2 is a high level signal, and the second pixel transistor PT2 is turned on. The first pixel transistor PT1 and the second pixel transistor PT2 are turned on such that the first initial signal provided by the first initial signal line INIT1 is provided to the first node PN1 to initialize the first node PN1. The second reset control signal RESET2 provided by the second reset control line RST2 is a high level signal, the first scan signal SCAN1 provided by the first scan line GL1 is a high level signal, and the light emitting control signal EM provided by the light emitting control line EML is a high level signal, so that the seventh pixel transistor PT7, the eighth pixel transistor PT8, the fourth pixel transistor PT4, the fifth pixel transistor PT5 and the sixth pixel transistor PT6 are turned off. In this stage, the light emitting element EL does not emit light.

The third stage S13 is referred to as a data writing stage or a threshold compensation stage. The first scan signal SCAN1 provided by the first scan line GL1 is a low level signal, and the fourth pixel transistor PT4 is turned on. The second scan signal SCAN2 provided by the second scan line GL2 is a high level signal, and the second pixel transistor PT2 is turned on. In this stage, the first electrode of the storage capacitor Cst is at a low level and the third pixel transistor PT3 is turned on. The second pixel transistor PT2, the fourth pixel transistor PT4 and the third pixel transistor PT3 are turned on, so that a data voltage Vdata output by the data line DL is provided to the first node PN1 through the second node PN2, the turned-on third pixel transistor PT3, the third node PN3, and the turned-on second pixel transistor PT2; and the storage capacitor Cst is charged with a difference between the data voltage Vdata output by the data line DL and a threshold voltage of the third pixel transistor PT3. A voltage of the first electrode (i.e., the first node PN1) of the storage capacitor Cst is Vdata−|Vth|, where Vdata is the data voltage output by the data line DL, and Vth is the threshold voltage of the third pixel transistor PT3. The first reset control signal RESET1 provided by the first reset control line RST1 is a high level signal, the second reset control signal RESET2 provided by the second reset control line RST2 is a high level signal, and the light emitting control signal EM provided by the light emitting control line EML is a high level signal, so that the first pixel transistor PT1, the seventh pixel transistor PT7, the eighth pixel transistor PT8, the fifth pixel transistor PT5 and the sixth pixel transistor PT6 are turned off.

In the fourth stage Si4, the light emitting control signal EM provided by the light emitting control line EML may be switched from the high level signal to a low level signal, so that the fifth pixel transistor PT5 and the sixth pixel transistor PT6 are turned on. The second scan signal SCAN2 provided by the second scan line GL2 is a low level signal, so that the second pixel transistor PT2 is turned off. The first scan signal SCAN1 provided by the first scan line GL1, the first reset control signal RESET1 provided by the first reset control line RST1, and the second reset control signal RESET2 provided by the second reset control line RST2 are high level signals, so that the fourth pixel transistor PT4, the first pixel transistor PT1, the seventh pixel transistor PT7, and the eighth pixel transistor PT8 are turned off. The first voltage signal VDD outputted by the first power supply line VDD may provide a drive voltage to the anode of the light emitting element EL through the fifth pixel transistor PT5, the third pixel transistor PT3, and the sixth pixel transistor PT6 which are turned on, to drive the light emitting element EL to emit light.

In a driving process of the pixel circuit, a drive current flowing through the third pixel transistor PT3 is determined by a voltage difference between the gate and the first electrode of the third pixel transistor T3. Since the voltage of the first node PN1 is Vdata−|Vth|, the drive current of the third pixel transistor PT3 is as follows:

$$I = K \times {( V gs - V th )}^{2} = K \times {[ ( V dd - V data + \vert V th \vert ) - V th ]}^{2} = K \times {[ V dd - V data ]}^{2} .$$

Herein, I is the drive current flowing through the third pixel transistor PT3, that is, a drive current for driving the light emitting element, K is a constant, Vgs is the voltage difference between the gate and the first electrode of the third pixel transistor PT3, Vth is the threshold voltage of the third pixel transistor PT3, Vdata is the data voltage output by the data line DL, and Vdd is the first voltage signal output by the first power supply line VDD.

It may be seen from the above formula that a current flowing through the light emitting element is independent of the threshold voltage of the third pixel transistor PT3. Therefore, the pixel circuit according to the present embodiment may better compensate the threshold voltage of the third pixel transistor PT3. Moreover, the pixel circuit provided in the present embodiment may improve poor display caused by low frequency and improve a display effect of the light emitting element.

In some examples, as shown in FIG. 1, the peripheral area BB may include a first bezel area (lower bezel) B1 and a third bezel area (upper bezel) B3 provided opposite to each other in the second direction Y, and two second bezel areas (including a left bezel B2a and a right bezel B2b) provided opposite to each in the first direction X. The first bezel area B1 is adjacent to the first edge of the display area AA, the third bezel area B3 is adjacent to the second edge of the display area AA, the left bezel B2a is adjacent to the third edge of the display area AA, and the right bezel B12b is adjacent to the fourth edge of the display area AA.

In some examples, as shown in FIG. 1, the peripheral area BB may further include four corner areas (including, for example, two first corner areas B4a and B4b, and two second corner areas B5a and B5b). The first bezel area B1 may be communicated with the left bezel B2a through the first corner area B4a, and the first bezel area B1 may be communicated with the right bezel B2b through the first corner area B4b. The third bezel area B3 may be communicated with the left bezel B2a through the second corner area B5a, and may also be communicated with the right bezel B2b through the second corner area B5b. The four corner areas may each correspond to an arc-shaped display boundary of the display area AA, and the corner areas may be located on a perimeter of the corresponding arc-shaped display boundary.

An edge of the corner area on a side away from the display area AA may be an arc-shaped edge.

In some examples, as shown in FIG. 1, the peripheral area BB may include a plurality of gate drive circuits (including, for example, at least one first gate drive circuit GA1 and at least one second gate drive circuit GA2). In some examples, a plurality of first gate drive circuits GA1 may be provided in the left bezel B2a, the first corner area B4a, and the second corner area B5a, and a plurality of second gate drive circuits GA2 may be provided in the right bezel B2b, the first corner area B4b, and the second corner area B5b.

In some examples, a quantity of the first gate drive circuits GA1 may be three, and they may include, for example, a first scan gate drive circuit providing a first scan signal, a second scan gate drive circuit providing a second scan signal, and a first reset gate drive circuit providing a first reset control signal. A quantity of the second gate drive circuits GA2 may be two, and they may include, for example, a second reset gate drive circuit providing a second reset control signal and a light emitting control gate drive circuit providing a light emitting control signal. However, the present embodiment is not limited thereto. In some other examples, the quantities of the first gate drive circuits GA1 and the second gate drive circuits GA2 may be the same.

In some examples, as shown in FIG. 1, each gate drive circuit may include a plurality of cascaded drive units. Each drive unit may be configured to provide a drive signal to at least one row of sub-pixels in the display area AA. The plurality of drive units of a single gate drive circuit may be provided sequentially in an extension direction of an edge of the display area AA.

In some examples, as shown in FIG. 1, the peripheral area BB may further include a second power supply line (which may also be referred to as a low potential power supply line) S_VSS. The second power supply line S_VSS may be located on a side of the plurality of gate drive circuits away from the display area AA, and may be electrically connected with the second power supply line connected by the light emitting elements in the display area AA. The second power supply line S_VSS may be substantially an annular structure. However, the present embodiment is not limited thereto.

In some examples, as shown in FIG. 1, the peripheral area BB may further include at least one constant voltage power supply line. Each constant voltage power supply line may include a first area constant voltage power supply line INITa located in the first bezel area B1 and a second area constant voltage power supply line INITb located at least in the second bezel areas (including the left bezel B2a and the right bezel B2b). The first area constant voltage power supply line INITa may be electrically connected with the second area constant voltage power supply line INITb transmitting the same signal. For example, the second area constant voltage power supply line INITb may extend from the left bezel B2a through the first corner area B4a to be electrically connected with the first area constant voltage power supply line INITa. The second area constant voltage power supply line INITb may also extend from the right bezel B2b through the first corner area B4b to be electrically connected with the first area constant voltage power supply line INITa.

In some examples, as shown in FIG. 1, pixel circuits of each row of sub-pixels in the display area may be connected with at least one constant voltage signal line INIT extending in the first direction X. The constant voltage signal line INIT connected by the pixel circuits of at least one row of sub-pixels close to the arc-shaped display boundary may be connected with the first area constant voltage power supply line INITa of the first bezel area B1, so as to reduce a quantity of traces in the first corner areas B4a and B4b, thereby facilitating the realization of a narrow bezel design.

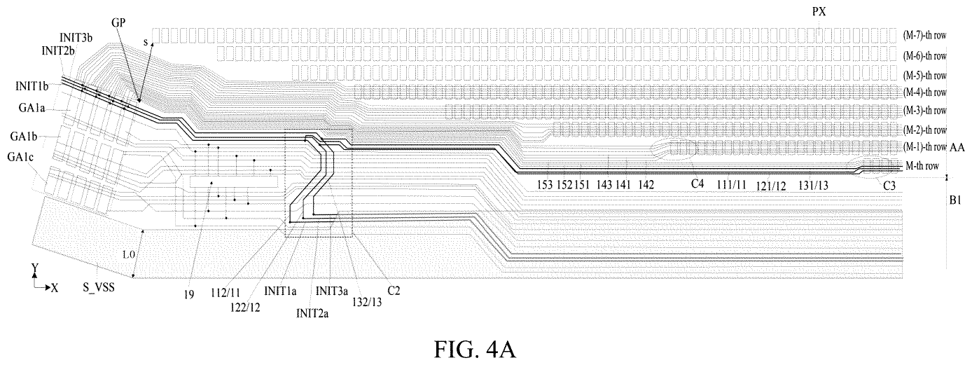

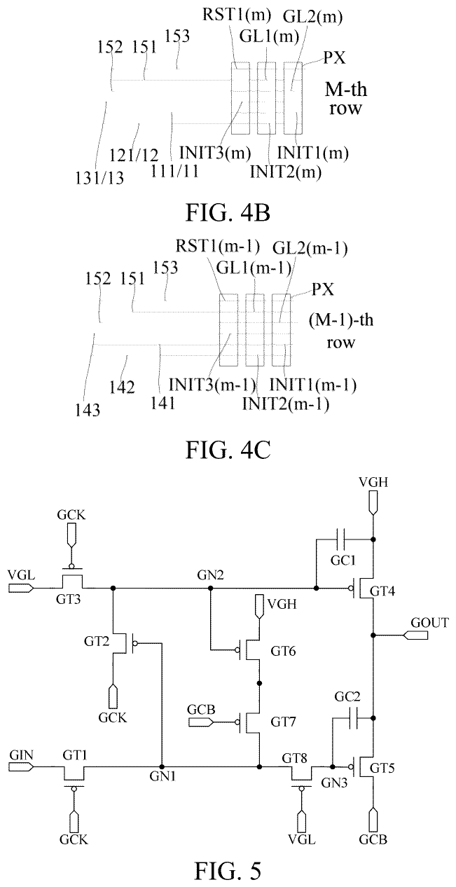

FIG. 4A is a schematic diagram of a partial structure of area C1 in FIG. 1. FIG. 4B is a schematic diagram of partial connection of area C3 in FIG. 4A. FIG. 4C is a schematic diagram of partial connection of area C4 in FIG. 4A. FIG. 4A is illustrated with an example of eight rows of sub-pixels (e.g., a (M−7)-th row to a M-th row of sub-pixels) close to the arc-shaped display boundary of the display area AA, where the M-th row of sub-pixels may be closest to the first bezel area B1, and M may be a positive integer. The M-th row of sub-pixels may be a last row of sub-pixels on the display substrate.

In some examples, as shown in FIGS. 4A to 4C, pixel circuits of each row of sub-pixels may be electrically connected with three constant voltage signal lines (including, for example, a first initial signal line INIT1, a second initial signal line INIT2, and a third initial signal line INIT3). At least one constant voltage signal line connected by the pixel circuits of the M-th row of sub-pixels may be connected with a first area constant voltage power supply line located in the first bezel area B1 through a first adapter line. The first area constant voltage power supply line of the first bezel area B1 may include a first initial power supply line INIT1a, a second initial power supply line INIT2a, and a third initial power supply line INIT3a. The second initial signal line INIT2(m) connected by the pixel circuits of the M-th row of sub-pixels may be electrically connected with the second initial power supply line INIT2a through a first adapter line 12, and the third initial signal line INIT3(m) connected by the pixel circuits of the M-th row of sub-pixels may be electrically connected with the third initial power supply line INIT3a through a first adapter line 13. The first initial signal line INIT1(m) located between the second initial signal line INIT2(m) and the third initial signal line INIT3(m) may be electrically connected with the first initial power supply line INIT1a through a first adapter line 11. In some examples, the pixel circuits of the M-th row of sub-pixels may be connected with a first initial signal line INIT1(m) closest to the first bezel area B1. Alternatively, the pixel circuits of the m-th row of sub-pixels may be connected with a first initial signal line INIT1(m−1) that is overlapped with an orthographic projection of pixel circuits of the (M−1)-th row of sub-pixels on the base substrate, and the first initial signal line INIT1(m) closest to the first bezel area B1 may serve as an auxiliary initial signal line to ensure the uniformity of traces in the display area without need of being connected with the pixel circuits.

In some examples, as shown in FIGS. 4A to 4C, each first adapter line may include a first sub-connection line and a second sub-connection line, and the first sub-connection line and the second sub-connection line are connected. An extending direction of the first sub-connection line and an extending direction of the second sub-connection line may intersect. For example, the first sub-connection line may have a bend line shape extending substantially in the first direction X, and the second sub-connection line may have a bend line shape extending substantially in the second direction Y. The first sub-connection line may include a line segment extending in the first direction X and a line segment extending in another direction intersecting with the first direction X. The second sub-connection line may include a line segment extending in the second direction Y and a line segment extending in another direction intersecting with the second direction Y. However, the present embodiment is not limited thereto. In some other examples, the first sub-connection line may extend in the first direction X, and the second sub-connection line may extend in the second direction Y.

For example, the first adapter line 11 may include a first sub-connection line 111 and a second sub-connection line 112. The first adapter line 12 may include a first sub-connection line 121 and a second sub-connection line 122. The first adapter line 13 may include a first sub-connection line 131 and a second sub-connection line 132. For example, a portion of each first adapter line may be located in the first corner area B4a.

In some examples, as shown in FIGS. 4A to 4C, at least one constant voltage signal line connected by the pixel circuits of the remaining rows of sub-pixels except the M-th row of sub-pixels (including, for example, the (M−7)-th to (M−1)-th rows of sub-pixels in FIG. 4A) may be connected with the second area constant voltage power supply line located in the first corner area B4a through the second adapter line. The second area constant voltage power supply line in the present example may include a fourth initial signal line INIT1b, a fifth initial power supply line INIT2b, and a sixth initial power supply line INIT3b. The fourth initial power supply line INIT1b may be connected with the first initial power supply line INIT1a and configured to transmit a first initial signal; the fifth initial power supply line INIT2b may be connected with the second initial power supply line INIT2a and configured to transmit a second initial signal; and the sixth initial power supply line INIT3b may be connected with the third initial power supply line INIT3a and configured to transmit a third initial signal.

In some examples, as shown in FIG. 4C, the first initial signal line INIT1(m−1) that is overlapped with the orthographic projection the pixel circuits of the (M−1)-th row of sub-pixels on the base substrate may be electrically connected with the fourth initial power supply line INIT1b through a second adapter line 141, the second initial signal line INIT2(m−1) connected by the pixel circuits of the (M−1)-th row of sub-pixels may be electrically connected with the fifth initial power supply line INIT2b through a second adapter line 142, and the third initial signal line INIT3(m−1) connected by the pixel circuits of the (M−1)-th row of sub-pixels may be electrically connected with the sixth initial power supply line INIT3b through a second adapter line 143. The second adapter lines 141, 142, and 143 may extend into the first corner area B4a and are connected with corresponding initial power supply lines.

In some examples, as shown in FIG. 4A, the left bezel B2a and the first corner area B4a may be provided with three first gate drive circuits (including, for example, a first scan gate drive circuit GA1a, a second scan gate drive circuit GA1b, and a first reset gate drive circuit GA1c). The first scan gate drive circuit GA1a, the second scan gate drive circuit GA1b, and the first reset gate drive circuit GA1c may be arranged sequentially in a direction away from the display area AA. Each first gate drive circuit may include a plurality of cascaded drive units. The first scan gate drive circuit GA1a may be configured to provide a first scan signal SCAN1 to the pixel circuits in the display area. For example, an output terminal of drive units at each stage in the first scan gate drive circuit GA1a may be electrically connected with a first scan line (e.g., a first scan lines GL1(m), or GL1(m−1)) connected by pixel circuits of a row of sub-pixels through a first drive connection line 151. The second scan gate drive circuit GA1b may be configured to provide a second scan signal SCAN2 to the pixel circuits in the display area. For example, an output terminal of drive units at each stage in the second scan gate drive circuit may be connected with two adjacent second drive connection lines 152 to be electrically connected with second scan lines (e.g., second scan lines GL2(m−1) and GL2(m)) connected by the pixel circuits of adjacent two rows of sub-pixels. The first reset gate drive circuit GA1c may be configured to provide a first reset control signal RESET1 to the pixel circuits in the display area. For example, an output terminal of drive units at each stage in the first reset gate drive circuit may be connected with two third drive connection lines 153 to be electrically connected with first reset control lines (e.g., first reset control lines RST1(m−1) and RST1(m)) connected by the pixel circuits of adjacent two rows of sub-pixels.

In some examples, the right bezel B2b and the second corner area B4b may be provided with two second gate drive circuits (which may include, for example, a second reset gate drive circuit and a light emitting control gate drive circuit). The second reset gate drive circuit may be configured to provide a second reset control signal RESET2 to the pixel circuits in the display area. The light emitting control gate drive circuit may be configured to provide a light emitting control signal EM to the pixel circuits in the display area.

In some examples, as shown in FIG. 4A, the first bezel area B1 may further include a plurality of drive control lines. The plurality of drive control lines may extend from the first bezel area B1 to the first corner area B4a, and are electrically connected with the first scan gate drive circuit GA1a, the second scan gate drive circuit GA1b, and the first reset gate drive circuit GA1c. The first initial power supply line INIT1a, the second initial power supply line INIT2a, and the third initial power supply line INIT3a may be located between the plurality of drive control lines.

In some examples, as shown in FIG. 4A, the first bezel area B1 may further be provided with a plurality of electrostatic discharge circuits 19. The plurality of drive control lines may be electrically connected with the plurality of electrostatic discharge circuits 19. For example, each drive control line may be connected with one electrostatic discharge circuit. The plurality of electrostatic discharge circuits 19 may be located between the second sub-connection line of the first adapter line and the three first gate drive circuits. The second sub-connection lines of the three first adapter lines may be located on a side of the plurality of electrostatic discharge circuits 19 away from the first gate drive circuit in the first direction X. The position for providing the first adapter line in the present example facilitates the trace arrangement.

In some examples, as shown in FIG. 4A, in order to guarantee a line width L0 of the second power supply line S_VSS, a cut-off position GP of the gate drive circuit is generally higher than a last row of sub-pixels (that is, the M-th row of sub-pixels in FIG. 4A). A line connection space (e.g., denoted s) between the cut-off position of the gate drive circuit and a closest sub-pixel row may be a product of a quantity of a row of sub-pixels that have not been connected (e.g., denoted n), a line width of the connection line (e.g., denoted p), and a quantity of the connection lines (e.g., denoted b), i.e., s=n*p*b. In the present example, for the first corner area after the size is reduced, by adapting the constant voltage signal line connected by the first row of sub-pixels to the first area constant voltage power supply line of the first bezel area, the quantity of the connection lines b may be reduced, so as to reduce the line connection space s between the cut-off position GP of the gate drive circuit and the closest sub-pixel row, thereby not only ensuring the normal connection and signal transmission between the gate drive circuit and the sub-pixels, but also facilitating the realization of a narrow bezel design.

In some examples, taking as an example that there are seven rows of sub-pixels below the cut-off position GP of the gate drive circuit that need to be connected with the gate drive circuit, the required line connection space between the cut-off position GP of the gate drive circuit and the closest sub-pixel row is s=7*4.2*6=176.4 μm, plus a distance between two outermost traces and adjacent traces of the same layer, that is, 6 μm on both sides, so that the required line connection space s is at least 182.4 μm. However, in some examples, when the corner area space is less than 1.0 mm, the actual line connection space s between the cut-off position GP and the closest sub-pixel row is only 177 μm. The present example may reduce traces in the first corner area by providing signals from the first bezel area to the first initial signal line, the second initial signal line, and the third initial signal line closest to the first bezel area. In the present example, the first initial signal line closest to the first bezel area serves only as an auxiliary initial signal line, which is not connected with the pixel circuits of the M-th row of sub-pixels, and may be connected with the second area constant voltage power supply line without extending to the first corner area. The pixel circuits of the M-th row of sub-pixels are connected with the second initial signal line and the third initial signal line closest to the first bezel area. In the present example, by providing that the second initial signal line and the third initial signal line connected by the pixel circuits of the last row of sub-pixels (that is, the M-th row of sub-pixel) are connected with the first area constant voltage power supply line of the first bezel area, the second adapter line required for connecting the second initial signal line and the third initial signal line connected by the pixel circuits of the last row of sub-pixels with the second area constant voltage power supply line may be saved. That is, two traces extending toward the gate drive circuit may be reduced. Therefore, the required line connection space may be reduced by a width of 2 traces, that is, 4.2*2=8.4 μm, so that the required line connection space s=182.4-8.4=174 μm<177 μm. The present example may meet the requirements for the narrow bezel design.

FIG. 5 is an equivalent circuit diagram of drive units of a first scan gate drive circuit according to at least one embodiment of the present disclosure. In some examples, as shown in FIG. 5, a drive unit of the first scan gate drive circuit may include eight transistors (i.e., a first shift transistor GT1, a second shift transistor GT2, a third shift transistor GT3, a fourth shift transistor GT4, a fifth shift transistor GT5, a sixth shift transistor GT6, a seventh shift transistor GT7, and an eighth shift transistor GT8) and two capacitors (a first capacitor GC1 and a second capacitor GC2). The fourth shift transistor GT4 and the fifth shift transistor GT5 are output transistors of the drive unit.

In some examples, as shown in FIG. 5, a control electrode of the first shift transistor GT1 is electrically connected with the first clock signal line GCK, a first electrode of the first shift transistor GT1 is electrically connected with a shift input terminal GIN, and a second electrode of the first shift transistor GT1 is electrically connected with a first shift node GN1. A control electrode of the second shift transistor GT2 is electrically connected with the first shift node GN1, a first electrode of the second shift transistor GT2 is electrically connected with a first clock signal line GCK, and a second electrode of the second shift transistor GT2 is electrically connected with a second shift node GN2. A control electrode of the third shift transistor GT3 is electrically connected with the first clock signal line GCK, a first electrode of the third shift transistor GT3 is electrically connected with the fourth power supply line VGL, and a second electrode of the third shift transistor GT3 is electrically connected with the second shift node GN2. A control electrode of the fourth shift transistor GT4 is electrically connected with the second shift node GN2, a first electrode of the fourth shift transistor GT4 is electrically connected with a third power supply line VGH, and a second electrode of the fourth shift transistor GT4 is electrically connected with the shift output terminal GOUT. A control electrode of the fifth shift transistor GT5 is electrically connected with a third shift node GN3, a first electrode of the fifth shift transistor GT5 is electrically connected with a second clock signal line GCB, and a second electrode of the fifth shift transistor GT5 is electrically connected with the shift output terminal GOUT. A control electrode of the sixth shift transistor GT6 is electrically connected with the second shift node GN2, a first electrode of the sixth shift transistor GT6 is electrically connected with the third power supply line VGH, and a second electrode of the sixth shift transistor GT6 is electrically connected with a first electrode of the seventh shift transistor GT7. A control electrode of the seventh shift transistor GT7 is electrically connected with a second clock signal line GCB, and a second electrode of the seventh shift transistor GT7 is electrically connected with the first shift node GN1. A control electrode of the eighth shift transistor GT8 is electrically connected with a fourth power supply terminal VGL, a first electrode of the eighth shift transistor GT8 is electrically connected with the first shift node GN1, and a second electrode of the eighth shift transistor GT8 is electrically connected with the third shift node GN3. A second electrode of the first capacitor GC1 is electrically connected with the third power supply line VGH, and a first electrode of the first capacitor GC1 is electrically connected with the second shift node GN2. A second electrode of the second capacitor GC2 is electrically connected with the shift output terminal GOUT, and a first electrode of the second capacitor GC2 is electrically connected with the third shift node GN3.

In some examples, as shown in FIG. 5, the first shift node GN1 is a connection point of the first shift transistor GT1, the second shift transistor GT2, the seventh shift transistor GT7, and the eighth shift transistor GT8. The second shift node GN2 is a connection point of the second shift transistor GT2, the third shift transistor GT3, the fourth shift transistor GT4, the sixth shift transistor GT6, and the first capacitor GC1. The third shift node GN3 is a connection point of the eighth shift transistor GT8, the fifth shift transistor GT5, and the second capacitor GC2.

In some examples, the first shift transistor GT1 to the eighth shift transistors GT8 of the first scan gate drive circuit shown in FIG. 5 may all be P-type transistors or N-type transistors. However, the present embodiment is not limited thereto.

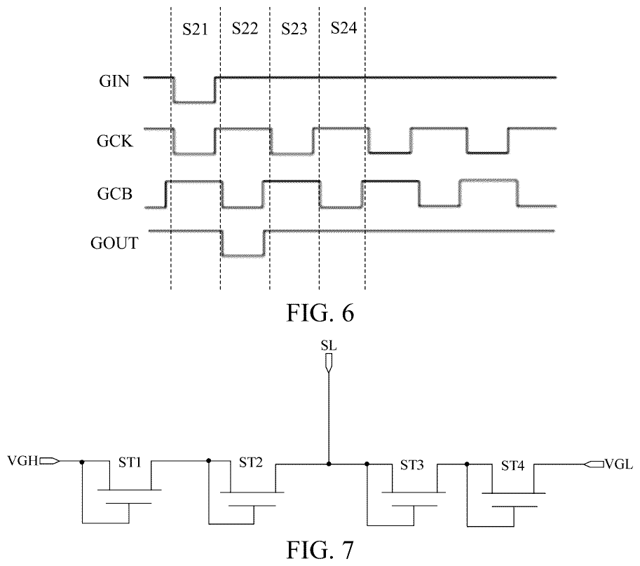

FIG. 6 is a working timing diagram of the drive units of the first scan gate drive circuit shown in FIG. 5. In some examples, illustration is made by taking an example in which the first shift transistor GT1 to the eighth shift transistor GT8 of the drive unit shown in FIG. 5 are all P-type transistors. Illustration is made by taking an example in which the shift input terminal GIN of a first-stage drive circuit is electrically connected with a first start signal line GSTV. As shown in FIGS. 5 and 6, the drive unit of the first gate scan drive circuit in the present exemplary embodiment may include eight transistor units (i.e., the first shift transistor GT1 to the eighth shift transistor GT8), two capacitor units (i.e., the first capacitor GC1 to the second capacitor GC2), three input terminals (i.e., the first clock signal line GCK, the second clock signal line GCB and the shift input terminal GIN), one output terminal (i.e., the shift output terminal GOUT), and two power supply terminals (i.e., the third power supply line VGH and the fourth power supply line VGL). The third power supply line VGH may be configured to continuously provide a high level signal, and the fourth power supply line VGL may be configured to continuously provide a low level signal.

In some examples, as shown in FIGS. 5 and 6, a wording process of the drive unit of the first gate scan drive circuit in the present example may include the following phases.

In a first phase S21, the first clock signal line GCK provides a first clock signal with a low level, the shift input terminal GIN receives a trigger signal with a low level, therefore, the first shift transistor GT1 and the third shift transistor GT3 are turned on, and the turned-on first shift transistor GT1 transmits the low level trigger signal to the first shift node GN1, such that a level of the first shift node GN1 becomes a low level, so the second shift transistor GT2 and the fifth shift transistor GT5 are turned on. Since the eighth shift transistor GT8 is always in a turned-on state in response to a fourth voltage signal (continuously maintaining at a low level) provided by the fourth power supply line VGL, a level of the third shift node GN3 may be the same as that of the first shift node GN1, i.e., at a low level, and meanwhile this low level is stored in the second capacitor GC2. In addition, the turned-on third shift transistor GT3 transmits a second voltage with a low level to the second shift node GN2, the turned-on second shift transistor GT2 transmits the low level of the first clock signal to the second shift node GN2, such that the level of the second shift node GN2 becomes a low level, and is stored in the first capacitor GC1, therefore, the fourth shift transistor GT4 is turned-on in response to the low level of the second shift node GN2. A third voltage signal with a high level provided by the third power supply line VGH is output to the shift output terminal GOUT, while the fifth shift transistor GT5 is turned-on in response to the low level of the third shift node GN3, so as to transmit a second clock signal with a high level provided by the second clock signal line GCB to the shift output terminal GOUT, such that the drive unit outputs a high level signal in this phase.

In a second phase S22, the second clock signal line GCB provides a second clock signal with a low level, so the seventh shift transistor GT7 is turned on, and the first clock signal line GCK provides a first clock signal with a high level, so the first shift transistor GT1 and the third shift transistor GT3 are turned off. Due to a storage effect of the second capacitor GC2, the first shift node GN1 may maintain at the low level of the previous phase, so the second shift transistor GT2 and the fifth shift transistor GT5 are turned on. Since the second shift transistor GT2 is turned on, the first clock signal with the high level of the first clock signal line GCK is transmitted to the second shift node GN2, such that the level of the second shift node GN2 becomes a high level, and therefore, the sixth shift transistor GT6 and the fourth shift transistor GT4 are turned off, thereby avoiding the high level provided by the third power supply line VGH from being output to the shift output terminal GOUT and the first shift node GN1. Meanwhile, since the fifth shift transistor GT5 is turned on, in this phase, the shift output terminal GOUT outputs the low level signal transmitted by the second clock signal line GGB.

In a third phase S23, the first clock signal line GCK provides a third clock signal with a low level, so the first shift transistor GT1 and the third shift transistor GT3 are turned on, and at this point, the high level provided by the scan initial signal line GSTV is transmitted from the shift input terminal GIN to the first shift node GN1 and the third shift node GN3, so the fifth shift transistor GT5 and the second shift transistor GT2 are turned off. The second clock signal line GCB receives a second clock signal with a high level, so the seventh shift transistor GT7 is turned off. Since the third shift transistor GT3 is turned on, the low level signal provided by the fourth power supply line VGL is transmitted to the second shift node GN2 and stored in the first shift GC1, such that the fourth shift transistor GT4 and the sixth shift transistor GT6 are turned on, and in this phase, the shift output terminal GOUT outputs the high level signal provided by the third power supply line VGH.

In a fourth phase S24, the first clock signal line GCK provides a first clock signal with a high level, so the first shift transistor GT1 and the third shift transistor GT3 are turned off. The second clock signal line GCB provides a second clock signal with a low level, so the seventh shift transistor GT7 is turned on. Due to a storage effect of the second capacitor GC2, the level of the first shift node GN1 maintains the high level of the previous phase, such that the second shift transistor GT2 and the fifth shift transistor GT5 are turned off. In this phase, the shift output terminal GOUT outputs a high level signal provided by the third power supply line VGH. Due to a storage effect of the first capacitor GC1, the second shift node GN2 continues maintaining the low level of the previous phase, such that the sixth shift transistor GT6 is turned on, then the high level provided by the third power supply line VGH is transmitted to the first shift node GN1 and the third shift node GN3 through the turned-on sixth shift transistor GT6 and the seventh shift transistor GT7, thus the first shift node GN1 and the third shift node GN3 continue maintaining the high level, and the fifth shift transistor GT5 is effectively prevented from being turned on, thereby avoiding an erroneous output.

In some examples, the drive unit may subsequently repeat the third phase S23 and the fourth phase S24 till the shift input terminal GIN receives a low level signal again.

FIG. 7 is an equivalent circuit diagram of an electrostatic discharge circuit according to at least one embodiment of the present disclosure. In some examples, as shown in FIG. 7, at least one electrostatic discharge circuit is connected with one signal line SL and configured to discharge static electricity in the signal line SL connected therewith. The electrostatic discharge circuit may prevent accumulation of static electricity in the signal line from causing discharge breakdown and resulting in damage, so as to release the static electricity accumulated in the signal line to protect the signal line.

In some examples, as shown in FIG. 7, the first electrostatic discharge circuit may include a first discharge transistor ST1 to a fourth discharge transistor ST4. A control electrode and a first electrode of the first discharge transistor ST1 are electrically connected with the third power supply line VGH; a second electrode of the first discharge transistor ST1 is electrically connected with a control electrode and a first electrode of the second discharge transistor ST2; a second electrode of the second discharge transistor ST2 is electrically connected with the signal line SL corresponding to the electrostatic discharge circuit; a control electrode and a first electrode of the third discharge transistor ST3 are electrically connected with the signal line SL corresponding to the electrostatic discharge circuit; a second electrode of the third discharge transistor ST3 is electrically connected with a control electrode and a first electrode of the fourth discharge transistor ST4; and a second electrode of the fourth discharge transistor ST4 is electrically connected with the fourth power supply line VGL.

In another example, the electrostatic discharge circuit may include two discharge transistors, wherein one electrode of each discharge transistor is connected with its own gate, thereby forming an equivalent diode connection. A signal line to be protected is connected between the two “diodes”, and another two terminals of the two “diodes” are respectively connected with the third power supply line VGH and the fourth power supply line VGL. Therefore, when an instantaneous high voltage (e.g., 100V) occurs due to accumulation of positive charges in the signal line, one of the “diodes” is turned on to discharge the positive charges in the signal line, and when an instantaneous low voltage (e.g., −100V) occurs due to accumulation of negative charges in the signal line, the other of the “diodes” is turned on to discharge the negative charges in the signal line.

In some examples, in a direction perpendicular to the display substrate, the peripheral area may at least include a first trace layer, a second trace layer, a third trace layer, and a fourth trace layer which are sequentially provided on the base substrate. At least one insulating layer may be provided between adjacent trace layers.

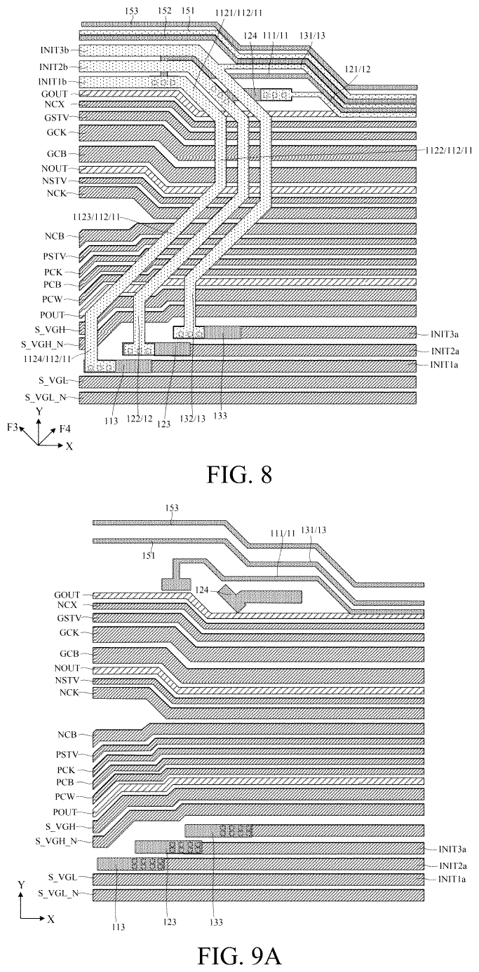

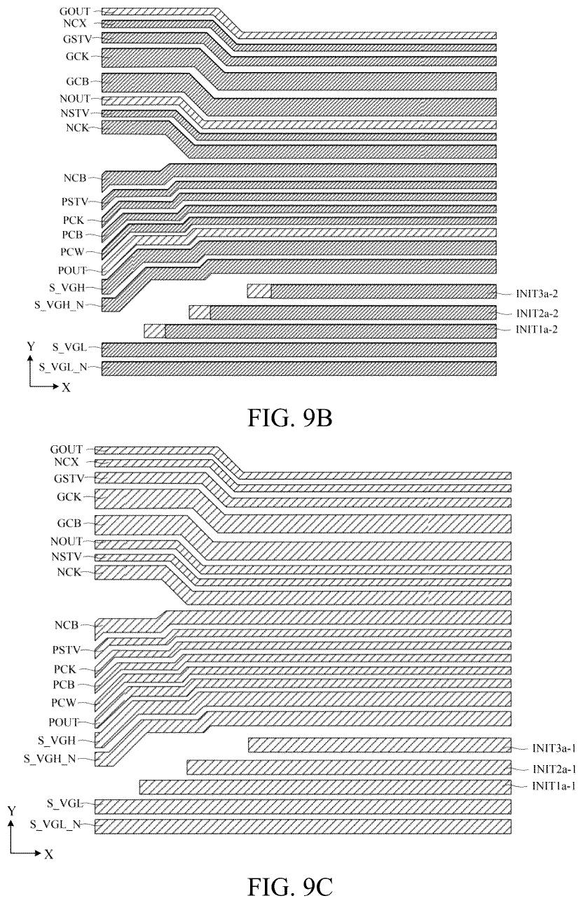

FIG. 8 is a schematic diagram of a partial structure of area C2 in FIG. 4A. FIG. 8 shows a schematic plan view of the area C2 after a fourth trace layer is formed. FIG. 9A is a schematic plan view of the area C2 in FIG. 8 after a third trace layer is formed. FIG. 9B is a schematic plan view of the area C2 in FIG. 8 after a second trace layer is formed; FIG. 9C is a schematic plan view of the area C2 in FIG. 8 after a first trace layer is formed.

In some examples, as shown in FIG. 8, the first bezel area may include a plurality of drive control lines, which may include a first drive output line GOUT, a first control line NCX, a first start signal line GSTV, a first clock signal line GCK, a second clock signal line GCB, a second drive output line NOUT, a second start signal line NSTV, a third clock signal line NCK, a fourth clock signal line NCB, a third start signal line PSTV, a fifth clock signal line PCK, a sixth clock signal line PCB, a third drive output line POUT, a third power supply line S_VGH, a fourth power supply line S_VGL, a fifth power supply line S_VGH_N, and a sixth power supply line S_VHL_N.

In some examples, the first drive output line GOUT, the first control line NCX, the first start signal line GSTV, the first clock signal line GCK, the second clock signal line GCB, the third power supply line S_VGH, and the fourth power supply line S_VGL may be electrically connected with the first scan gate drive circuit. The second drive output line NOUT, the second start signal line NSTV, the third clock signal line NCK, the fourth clock signal line NCB, the fifth power supply line S_VGH_N, and the sixth power supply line S_VHL_N may be electrically connected with the second scan gate drive circuit. The third start signal line PSTV, the fifth clock signal line PCK, the sixth clock signal line PCB, the third drive output line POUT, the third power supply line S_VGH, and the fourth power supply line S_VGL may be electrically connected with the first reset gate drive circuit.

In some examples, the electrostatic discharge circuit connected by the plurality of drive control lines may be located between the third clock signal line NCK and the fourth clock signal line NCB in the second direction Y.

In some examples, the first drive output line GOUT, the second drive output line NOUT, and the third drive output line POUT may be single-layer traces, for example, may be located on the first trace layer. The first control line NCX, the first start signal line GSTV, the first clock signal line GCK, the second clock signal line GCB, the second start signal line NSTV, the third clock signal line NCK, the fourth clock signal line NCB, the third start signal line PSTV, the fifth clock signal line PCK, the sixth clock signal line PCB, the third power supply line S_VGH, the fourth power supply line S_VGL, the fifth power supply line S_VGH_N, and the sixth power supply line S_VHL_N may all be double-layer traces. Each double-layer trace may include a first sub-trace located on the first trace layer and a second sub-trace located on the second trace layer. An orthographic projection of the first sub-trace on the base substrate may be at least partially overlapped with an orthographic projection of the second sub-trace on the base substrate, e.g., the orthographic projection of the first sub-trace on the base substrate may cover the orthographic projection of the second sub-trace on the base substrate.

In some examples, as shown in FIG. 8, the first initial power supply line INIT1a, the second initial power supply line INIT2a, and the third initial power supply line INIT3a may be located between the fifth power supply line S_VGH_N and the fourth power supply line S_VGL. The first initial power supply line INIT1a, the second initial power supply line INIT2a, and the third initial power supply line INIT3a may be arranged sequentially in a direction close to the display area. The first initial power supply line INIT1a, the second initial power supply line INIT2a, and the third initial power supply line INIT3a may all be double-layer traces. As shown in FIGS. 9B and 9C, the first initial power supply line INIT1a may include a first sub-trace INIT1a-1 located on the first trace layer and a second sub-trace INIT1a-2 located on the second trace layer; the second initial power supply line INIT2a may include a first sub-trace INIT2a-1 located on the first trace layer and a second sub-trace INIT2a-2 located on the second trace layer; and the third initial power supply line INIT3a may include a first sub-trace INIT3a-1 located on the first trace layer and a second sub-trace INIT3a-2 located on the second trace layer.

In some examples, the fourth initial power supply line INIT1b, the fifth initial power supply line INIT2b, and the sixth initial power supply line INIT3b may be located on a side of the first drive output line GOUT close to the second direction Y, for example, on a side close to the display area. The fourth initial power supply line INIT1b, the fifth initial power supply line INIT2b, and the sixth initial power supply line INIT3b may be arranged sequentially in a direction close to the display area. The fourth initial power supply line INIT1b, the fifth initial power supply line INIT2b, and the sixth initial power supply line INIT3b may be in a same layer structure, for example, all located in the fourth trace layer.

In some examples, as shown in FIG. 8, the first adapter line 11 may include a first sub-connection line 111 extending in at least the first direction X and a second sub-connection line 112 extending in at least the second direction Y, the first sub-connection line 111 and the second sub-connection line 112 being connected. The first sub-connection line 111 may have a bend line shape extending in the first direction X, and the second sub-connection line 112 may have a bend line shape extending in the second direction Y. The first sub-connection line 111 may be located on the third trace layer, and the second sub-connection line 112 may be located on the fourth trace layer. One end of the second sub-connection line 112 may be connected with the first sub-connection line 111, and the other end may be connected with the first sub-trace INIT1a-1 and the second sub-trace INIT1a-2 of the first initial power supply line INIT1a through a first connection electrode 113 located on the third trace layer. The second sub-connection line 112 and the fourth initial power supply line INIT1b may be of an interconnected integral structure.

In some examples, as shown in FIG. 8, the second sub-connection line 112 may include a first line segment 1121 extending in a third direction F3, a second line segment 1122 extending in the second direction Y, a third line segment 1123 extending in a fourth direction F4, and a fourth line segment 1124 extending in the second direction Y. The third direction F3 may intersect with both the first direction X and the second direction Y, the fourth direction F4 may intersect with both the first direction X and the second direction Y, and the third direction F3 may intersect with the fourth direction F4, for example, the third direction F3 may be perpendicular to the fourth direction F4. The first line segment 1121, the second line segment 1122, the third line segment 1123, and the fourth line segment 1124 may be connected sequentially. The first line segment 1121 and the fourth initial power supply line INIT 1B may be of an interconnected integral structure, and an end portion of the first line segment 1121 may be connected with the first sub-connection line 111. An end portion of the fourth line segment 1124 may be connected with the first initial power supply line INIT1a through the first connection electrode 113. The first line segment 1121, the second line segment 1122, the third line segment 1123, and the fourth line segment 1124 in the present example may be sequentially connected to form the second sub-connection line 112 having a bend line shape and extending substantially in the second direction Y.

In some examples, as shown in FIG. 8, the first adapter line 12 may include a first sub-connection line 121 extending in at least the first direction X and a second sub-connection line 122 extending in at least the second direction Y, the first sub-connection line 121 and the second sub-connection line 122 being connected. The first sub-connection line 121 may have a bend line shape extending in the first direction X, and may be located on a side of the first sub-connection line 111 in an opposite direction of the second direction Y. The second sub-connection line 122 may have a bend line shape extending in the second direction Y, and may be located on a side of the second sub-connection line 112 in the first direction X. The first sub-connection line 121 may be located on the fourth trace layer, and the second sub-connection line 122 may be located on the fourth trace layer. One end of the second sub-connection line 122 may be connected with the first sub-connection line 121 located on the fourth trace layer through a fourth connection electrode 124 located on the third trace layer, and the other end may be connected with the first sub-connection line INIT2a-1 located on the first trace layer and the second sub-connection line INIT2a-2 located on the second trace layer of the second initial power supply line INIT2a through a second connection electrode 123 located on the third trace layer. The second sub-connection line 122 and the fifth initial power supply line INIT2b may be of an interconnected integral structure. The shape of the second sub-connection line 122 may be referred to the description of the second sub-connection line 112, which will not be described here in detail.

In some examples, as shown in FIG. 8, the first adapter line 13 may include a first sub-connection line 131 extending in at least the first direction X and a second sub-connection line 132 extending in at least the second direction Y, the first sub-connection line 131 and the second sub-connection line 132 being connected. The first sub-connection line 131 may have a bend line shape extending in the first direction X, and may be located on a side of the first sub-connection line 111 in the second direction Y. The second sub-connection line 132 may have a bend line shape extending in the second direction Y, and may be located on a side of the second sub-connection line 122 in the first direction X. The first sub-connection line 131 may be located on the fourth trace layer, and the second sub-connection line 132 may be located on the fourth trace layer. The first sub-connection line 131 and the second sub-connection line 132 may be of an interconnected integral structure. The second sub-connection line 132 may be connected with the first sub-trace INIT3a-1 located on the first trace layer and the second sub-trace INIT3a-2 located on the second trace layer of the third initial power supply line INIT3a through the third connection electrode 133 located on the third trace layer. The second sub-connection line 132 and the sixth initial power supply line INIT 3b may be of an interconnected integral structure. The shape of the second sub-connection line 132 may be referred to the description of the second sub-connection line 112, which will not be described here in detail.

In some examples, as shown in FIG. 8, the first drive connection line 151, the second drive connection line 152, and the third drive connection line 153 connected by the pixel circuits of the M-th row of sub-pixels may be located on a side of the first sub-connection line 131 of the first adapter line 13 close to the display area. For example, the first drive connection line 151 may be located on the fourth trace layer, and the second drive connection line 152 and the third drive connection line 153 may be located on the third trace layer. In the present example, a plurality of traces in the first corner area may be provided on the third trace layer and the fourth trace layer, and adjacent traces may be located on different film layers to increase the trace arrangement space.

In some exemplary examples, in a direction perpendicular to the display substrate, the display substrate may include a first semiconductor layer, a first conductive layer, a second conductive layer, a second semiconductor layer, a third conductive layer, a fourth conductive layer, a fifth conductive layer, and a sixth conductive layer which are provided on the base substrate. A first insulating layer may be provided between the first semiconductor layer and the first conductive layer, a second insulating layer may be provided between the first conductive layer and the second conductive layer, a third insulating layer may be provided between the second conductive layer and the second semiconductor layer, a fourth insulating layer may be provided between the second semiconductor layer and the third conductive layer, a fifth insulating layer may be provided between the third conductive layer and the fourth conductive layer, a sixth insulating layer and a seventh insulating layer may be provided between the fourth conductive layer and the fifth conductive layer, and an eighth insulating layer may be provided between the fifth conductive layer and the sixth conductive layer. In some examples, the first insulating layer to the sixth insulating layer may be inorganic insulating layers, and the seventh insulating layer to the eighth insulating layer may be organic insulating layers. However, the present embodiment is not limited thereto.

In some examples, the first trace layer in the peripheral area may be located on the first conductive layer, the second trace layer may be located on the second conductive layer, the third trace layer may be located on the fourth conductive layer, and the fourth trace layer may be located on the fifth conductive layer.

The film layer structure of the display substrate of the present example will be illustrated below by a preparation process of the display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are provided in a same layer” or “A and B are of a same layer structure” in the present disclosure means that A and B are formed simultaneously through a same patterning process, or distances between surfaces of A and B close to a base substrate and the base substrate are substantially the same, or the surfaces of A and B close to the base substrate are in direct contact with a same film layer. A “thickness” of a film is a dimension of the film in a direction perpendicular to the display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B. The “shape of A” in the present disclosure refers to the shape of an orthographic projection of A on the base substrate.

In some examples, the preparing process of the display substrate may include the following operations. In the following example, film layers of a partial structure of four rows of pixel circuits and four drive units of the first scan gate drive circuit in the area C1 are taken as an example for illustration.

(1) A base substrate is provided. In some examples, the base substrate may be a rigid base or a flexible base. For example, the rigid base may be made of, but not limited to, one or more of glass and quartz. The flexible base substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base may include a first flexible material layer, a first inorganic material layer, a second flexible material layer and a second inorganic material layer which are stacked. The first flexible material layer and the second flexible material layer may be made of a material such as polyimide (PI), polyethylene terephthalate (PET), or a polymer soft film on which surface treatment is performed, and materials of the first inorganic material layer and the second inorganic material layer may be silicon nitride (SiNy, y>0) or silicon oxide (SiOx, x>0), etc., which are used to improve resistance to water and oxygen of the base substrate.

(2) A first semiconductor layer is formed. In some examples, a first semiconductor thin film is deposited on the base substrate, and the first semiconductor thin film is patterned through a patterning process to form the first semiconductor layer provided on the base substrate. In some examples, a material of the first semiconductor layer may be amorphous silicon (a-Si), polycrystalline silicon (p-Si), hexathiophene or polythiophene, or other materials.

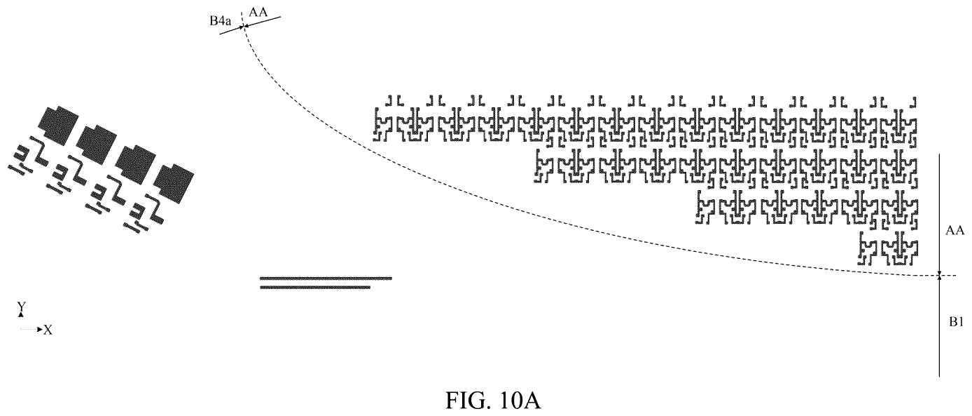

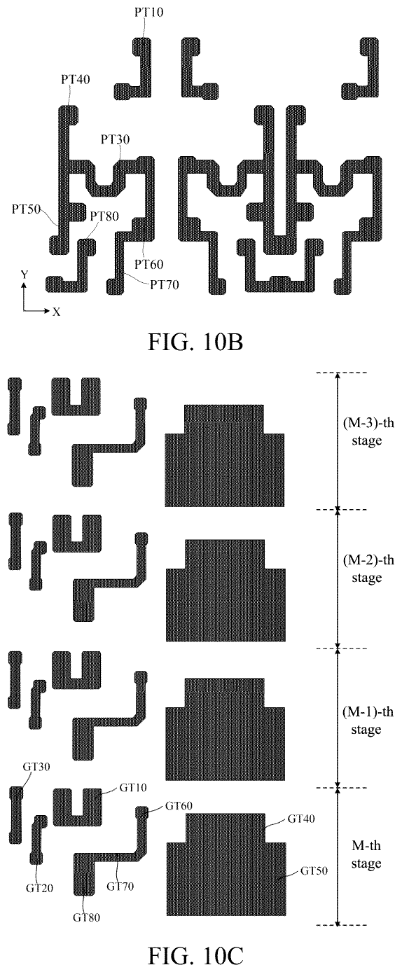

FIG. 10A is a partial schematic diagram of area C1 after a first semiconductor layer is formed. FIG. 10B is a partial schematic diagram of a display area after a first semiconductor layer is formed. FIG. 10C is a partial schematic diagram of a first corner area after a first semiconductor layer is formed. FIG. 10B illustrates a first semiconductor layer of three pixel circuits of a row of sub-pixels (such as the M-th row of sub-pixels in FIG. 4A) closest to the first bezel area in area C1. FIG. 10C illustrates a first semiconductor layer of four cascaded drive units (such as drive units at a (M−3)-th stage to a M-th stage) of the first scan gate drive circuit located in the first corner area in area C1.

In some examples, as shown in FIGS. 10A and 10B, the first semiconductor layer of the display area AA may at least include active layers of a plurality of first-type transistors of a pixel circuit (for example, an active layer PT10 of the first pixel transistor PT1, an active layer PT30 of the third pixel transistor PT3, an active layer PT40 of the fourth pixel transistor PT4, an active layer PT50 of the fifth pixel transistor PT5, an active layer PT60 of the sixth pixel transistor PT6, an active layer PT70 of the seventh pixel transistor PT7 and an active layer PT80 of the eighth pixel transistor PT8).

In some examples, an active layer of each transistor may include a first region, a second region, and a channel region located between the first region and the second region. A material of the first semiconductor layer may include, for example, polysilicon. The channel region may not be doped with an impurity, and has characteristics of a semiconductor. The first region and the second region may be doped regions on both sides of the channel region, and are doped with impurities, and thus have conductivity. The impurities may be changed according to a type of a transistor. In some examples, a doped region of the active layer may be interpreted as a source or a drain of a transistor. A portion of an active layer between the transistors may be interpreted as a wiring doped with an impurity, and may be used for electrically connecting the transistors. The present embodiment is not limited thereto.

In some examples, as shown in FIG. 10B, the active layer PT10 of the first pixel transistor and the active layer PT40 of the fourth pixel transistor may be located on a side of the active layer PT30 of the third pixel transistor in the second direction Y, and the active layer PT50 of the fifth pixel transistor, the active layer PT60 of the sixth pixel transistor, the active layer PT70 of the seventh pixel transistor, and the active layer PT80 of the eighth pixel transistor may be located on a side of the active layer PT30 of the third pixel transistor in an opposite direction of the second direction Y. The active layer PT80 of the eighth pixel transistor may be located on a side of the active layer PT70 of the seventh pixel transistor in an opposite direction of the first direction X.

In some examples, the active layer PT30 of the third pixel transistor, the active layer PT40 of the fourth pixel transistor, the active layer PT50 of the fifth pixel transistor, the active layer PT60 of the sixth pixel transistor, and the active layer PT70 of the seventh pixel transistor of a single pixel circuit may be of an interconnected integral structure. The first region of the active layer PT30 of the third pixel transistor may simultaneously serve as the second region of the active layer PT40 of the fourth pixel transistor and the second region of the active layer PT50 of the fifth pixel transistor, and the second region of the active layer PT30 of the third pixel transistor may simultaneously serve as the first region of the active layer PT60 of the sixth pixel transistor. The second region of the active layer PT60 of the sixth pixel transistor may simultaneously serve as the second region of the active layer PT70 of the seventh pixel transistor. The first region of the active layer PT40 of the fourth pixel transistor, the first region of the active layer PT50 of the fifth pixel transistor, and the first region of the seventh pixel transistor PT70 may be independently provided.

In some examples, the active layer PT30 of the third pixel transistor may be substantially U-shaped; the active layer PT40 of the fourth pixel transistor and the active layer PT50 of the fifth pixel transistor may be substantially I-shaped; and the active layer PT60 of the sixth pixel transistor, the active layer PT70 of the seventh pixel transistor, the active layer PT10 of the first pixel transistor, and the active layer PT80 of the eighth pixel transistor may be substantially L-shaped. The present embodiment is not limited thereto.

In some examples, a row of pixel circuits may include at least one pixel circuit group, and each pixel circuit group may include two pixel circuits symmetrically provided with respect to a center line of the pixel circuit group in the first direction X. For example, the active layers PT30 of the third pixel transistors, the active layers PT40 of the fourth pixel transistors, the active layers PT50 of the fifth pixel transistors, the active layers PT60 of the sixth pixel transistors, and the active layers PT70 of the seventh pixel transistors of two pixel circuits in one pixel circuit group may be of an interconnected integral structure.

In some examples, as shown in FIGS. 10A and 10C, the first semiconductor layer in the first corner area B4a may at least include active layers of a plurality of transistors of the drive unit of the first scan gate drive circuit (including, for example, an active layer GT10 of the first shift transistor, an active layer GT20 of the second shift transistor, an active layer GT30 of the third shift transistor, an active layer GT40 of the fourth shift transistor, an active layer GT50 of the fifth shift transistor, an active layer GT60 of the sixth shift transistor, an active layer GT70 of the seventh shift transistor, and an active layer GT80 of the eighth shift transistor).

In some examples, as shown in FIG. 10C, the active layer GT40 of the fourth shift transistor and the active layer GT50 of the fifth shift transistor of a single drive unit may be of an interconnected integral structure. The second region of the active layer GT40 of the fourth shift transistor may simultaneously serve as the second region of the active layer GT50 of the fifth shift transistor. The active layer GT60 of the sixth shift transistor, the active layer GT70 of the seventh shift transistor, and the active layer GT80 of the eighth shift transistor of the single drive unit may be of an interconnected integral structure, and the integral structure may be located on a side of the active layer GT40 of the fourth shift transistor and the active layer GT50 of the fifth shift transistor in the opposite direction of the first direction X. The second region of the active layer GT60 of the sixth shift transistor may simultaneously serve as the first region of the active layer GT70 of the seventh shift transistor, and the second region of the active layer GT70 of the seventh shift transistor may simultaneously serve as the first region of the active layer GT80 of the eighth shift transistor.

In some examples, as shown in FIG. 10C, the active layer GT10 of the first shift transistor may be located on a side of the active layer GT60 of the sixth shift transistor in the opposite direction of the first direction X. The active layer GT10 of the first shift transistor may be substantially U-shaped. The active layer GT20 of the second shift transistor and the active layer GT30 of the third shift transistor may be located on a side of the active layer GT10 of the first shift transistor in the opposite direction of the first direction X.

In some examples, as shown in FIG. 10A, the first semiconductor layer in the first bezel area B1 may at least include active layers of a plurality of discharge transistors of a plurality of electrostatic discharge circuits. For example, the plurality of electrostatic discharge circuits may be arranged in two rows. Each row may include a plurality of electrostatic discharge circuits, and active layers of a plurality of discharge transistors of a plurality of electrostatic discharge circuits in one row may be of an interconnected integral structure.

(3) A first conductive layer is formed. In some examples, a first insulating thin film and a first conductive thin film are deposited sequentially on the base substrate on which the aforementioned structures are formed, and the first conductive thin film is patterned through a patterning process to form a first insulating layer and a first conductive layer provided on the first insulating layer. In some examples, the first conductive layer may also be referred to as a first gate metal layer and the first insulating layer may also be referred to as a first gate insulating layer.

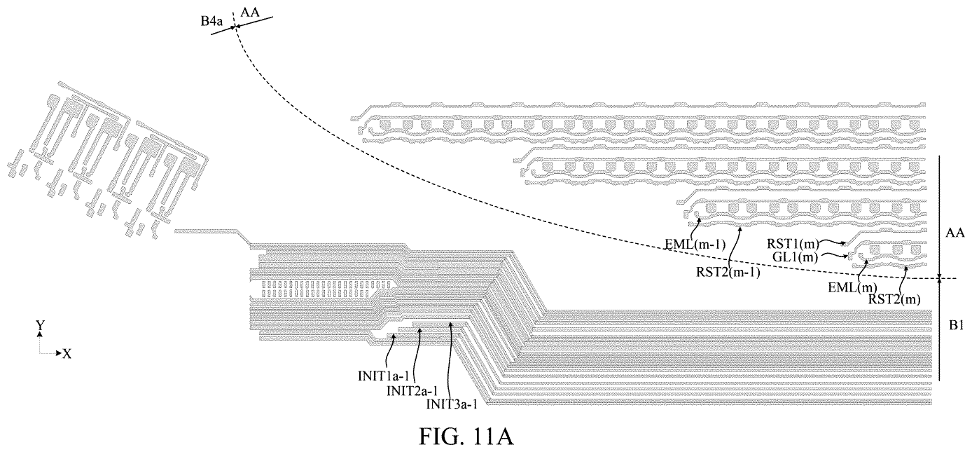

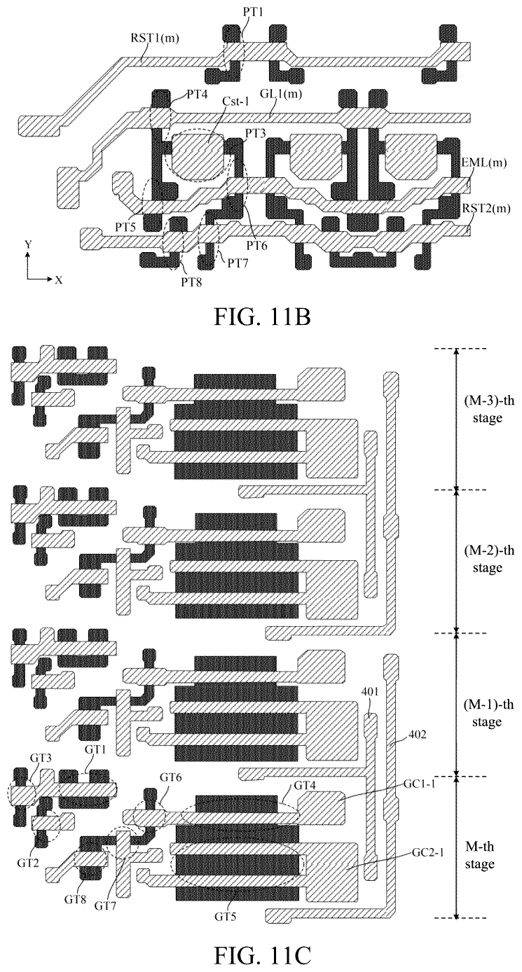

FIG. 11A is a partial schematic diagram of a first conductive layer of area C1. FIG. 11B is a partial schematic diagram of a display area after a first conductive layer is formed. FIG. 11C is a partial schematic diagram of a first corner area after a first conductive layer is formed. FIG. 11B illustrates three pixel circuits in a row of sub-pixels closest to the first bezel area after the first conductive layer is formed. FIG. 11C illustrates four cascaded drive units of the first scan gate drive circuit after the first conductive layer is formed.

In some examples, as shown in FIGS. 11A and 111B, the first conductive layer in the display area AA may at least include a first electrode (e.g., a first electrode Cst-1) of the storage capacitor of the pixel circuit, a plurality of first scan lines (including, for example, a first scan line GL1(m)), a plurality of first reset control lines (including, for example, a first reset control line RST1(m)), a plurality of second reset control lines (including, for example, second reset control lines RST2(m) and RST2(m−1)), and a plurality of light emitting control lines (including, for example, light emitting control lines EML(m) and EML(m−1)).

In some examples, as shown in FIG. 111B, an overlapping region of the first electrode Cst-1 of the storage capacitor with the active layer PT30 of the third pixel transistor PT3 may serve as a gate of the third pixel transistor PT3. An overlapping region of the first scan line GL1(m) with the active layer PT40 of the fourth pixel transistor PT4 of the pixel circuit may serve as a gate of the fourth pixel transistor PT4. An overlapping region of the first reset control line RST1(m) with the active layer PT10 of the first pixel transistor PT1 of the pixel circuit may serve as a gate of the first pixel transistor PT1. An overlapping region of the second reset control line RST2(m) with the active layer PT70 of the seventh pixel transistor PT7 of the pixel circuit may serve as a gate of the seventh pixel transistor PT7, and an overlapping region of the second reset control line RST2(m) with the active layer PT80 of the eighth pixel transistor PT8 may serve as a gate of the eighth pixel transistor PT8. An overlapping region of the light emission control line EML(m) with the active layer PT50 of the fifth pixel transistor PT5 of the pixel circuit may serve as a gate of the fifth pixel transistor PT5, and an overlapping region of the light emission control line EML(m) with the active layer PT60 of the sixth pixel transistor PT6 may serve as a gate of the sixth pixel transistor PT6.

In some examples, as shown in FIGS. 11A and 11C, the first conductive layer of the first corner area B4a may at least include gates of a plurality of transistors of the drive unit of the first scan gate drive circuit, the first electrode GC1-1 of the first capacitor and the first electrode GC2-1 of the second capacitor, a first output connection electrode 401 and a second output connection electrode 402.

In some examples, as shown in FIG. 11C, the gate of the first shift transistor GT1 and the gate of the third shift transistor GT3 may be of an interconnected integral structure. The gate of the sixth shift transistor GT6, the gate of the fourth shift transistor GT4, and the first electrode GC1-1 of the first capacitor may be of an interconnected integral structure. The gate of the fifth shift transistor GT5 and the first electrode GC2-1 of the second capacitor may be of an interconnected integral structure.

In some examples, as shown in FIG. 11C, the first output connection electrode 401 may be substantially T-shaped and the second output connection electrode 402 may be substantially L-shaped. At least a portion of the first output connection electrode 401 and at least a portion of the second output connection electrode 402 may be located on a side of the gates of the fourth shift transistor GT4 and the fifth shift transistor GT5 in the first direction X. At least a portion of the first output connection electrode 401 and at least a portion of the second output connection electrode 402 may be provided between the drive units at intervals. For example, the first output connection electrode 401 may be led out between a M-th-stage drive unit and a (M−1)-th-stage drive unit, the second output connection electrode 402 may be led out between the (M−1)-th-stage drive unit and a (M−2)-th-stage drive unit, and the first output connection electrode 401 may be led out between the (M−2)-th-stage drive unit and a (M−3)-th-stage drive unit.

In some examples, as shown in FIG. 11A, the first conductive layer of the first bezel area B1 may at least include a first sub-trace INIT1a-1 of the first initial power supply line, a first sub-trace INIT2a-1 of the second initial power supply line, a first sub-trace INIT3a-1 of the third initial power supply line, first sub-traces of a plurality of drive control lines, and gates of discharge transistors of a plurality of electrostatic discharge circuits. The first sub-trace INIT1a-1 of the first initial power supply line, the first sub-trace INIT2a-1 of the second initial power supply line, and the first sub-trace INIT3a-1 of the third initial power supply line may be sequentially arranged adjacent in a direction close to the display area AA, and the first sub-trace INIT1a-1 of the first initial power supply line, the first sub-trace INIT2a-1 of the second initial power supply line, and the first sub-trace INIT3a-1 of the third initial power supply line may be located between the first sub-traces of the plurality of drive control lines.

(4) A second conductive layer is formed. In some examples, a second insulating thin film and a second conductive thin film are deposited sequentially on the base substrate on which the aforementioned structures are formed, and the second conductive thin film is patterned through a patterning process to form a second insulating layer and a second conductive layer provided on the second insulating layer. In some examples, the second conductive layer may also be referred to as a second gate metal layer and the second insulating layer may also be referred to as a second gate insulating layer.

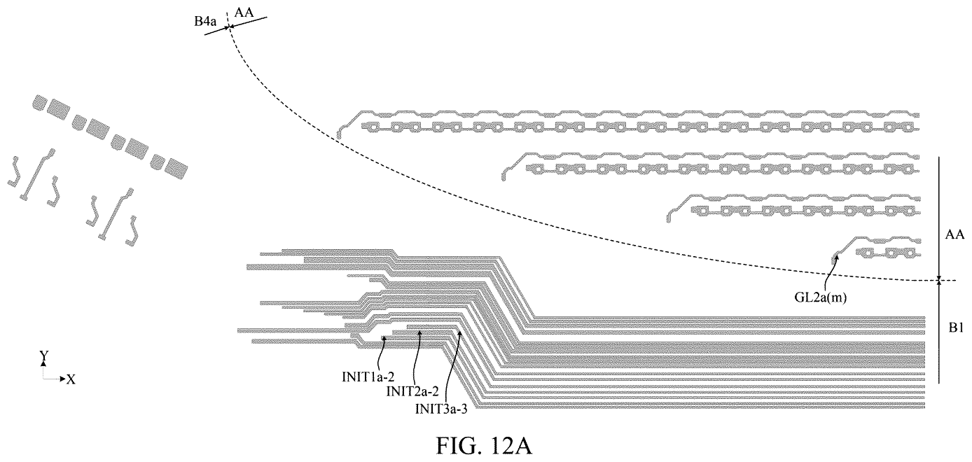

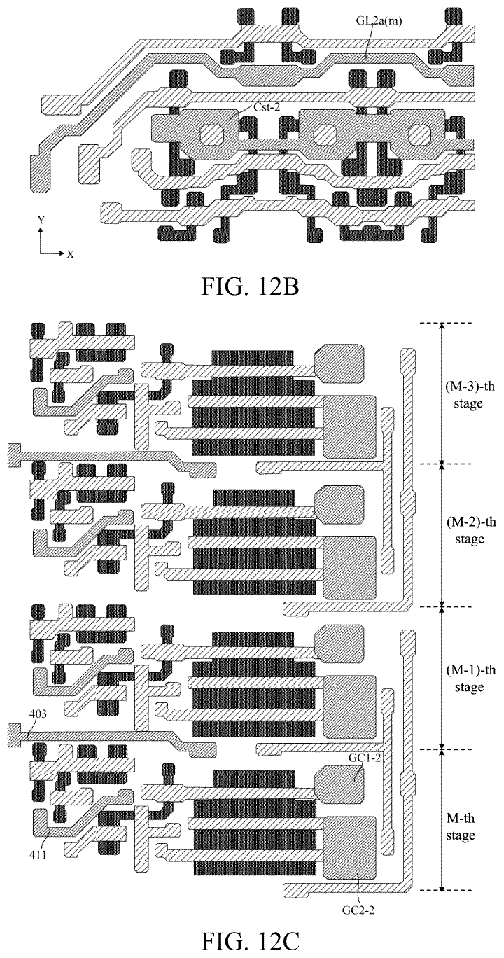

FIG. 12A is a partial schematic diagram of a second conductive layer of area C1. FIG. 12B is a partial schematic diagram of a display area after a second conductive layer is formed. FIG. 12C is a partial schematic diagram of a first corner area after a second conductive layer is formed. FIG. 12B illustrates three pixel circuits in a row of sub-pixels closest to the first bezel area after the second conductive layer is formed. FIG. 12C illustrates four cascaded drive units of the first scan gate drive circuit after the second conductive layer is formed.

In some examples, as shown in FIGS. 12A and 12B, the second conductive layer of the display area AA may at least include a second electrode of the storage capacitor of the pixel circuit (e.g., a second electrode Cst-2), a plurality of second scan auxiliary lines (including, for example, a second scan assist line GL2a(m)). The second electrodes Cst-2 of adjacent pixel circuits in a row of pixel circuits may be of an interconnected integral structure so as to realize transmission of the first voltage signal in the first direction X. An orthographic projection of the second scan auxiliary line GL2a(m) on the base substrate may be located between an orthographic projection of the first reset control line RST1(m) on the base substrate and an orthographic projection of the first scan line GL1(m) on the base substrate.

In some examples, as shown in FIGS. 12A and 12C, the second conductive layer of the first corner area B4a may at least include a second electrode GC1-2 of the first capacitor and a second electrode GC2-2 of the second capacitor of the drive unit of the first scan gate drive circuit, a third output connection electrode 403, and a first shift connection electrode 411. The third output connection electrode 403 may be arranged in alignment with a portion where the first output connection electrode 401 is inserted into the two drive units.

In some examples, as shown in FIG. 12A, the second conductive layer of the first bezel area B1 may at least include a second sub-trace INIT1a-2 of the first initial power supply line, a second sub-trace INIT2a-2 of the second initial power supply line, a third sub-trace INIT3a-2 of the third initial power supply line, and second sub-traces of a plurality of drive control lines.

The second sub-trace INIT1a-2 of the first initial power supply line, the second sub-trace INIT2a-2 of the second initial power supply line, and the third sub-traces INIT3a-2 of the third initial power supply line may be sequentially arranged adjacent in a direction close to the display area AA, and the second sub-trace INIT1a-2 of the first initial power supply line, the second sub-trace INIT2a-2 of the second initial power supply line, and the third sub-trace INIT3a-2 of the third initial power supply line may be located between the second sub-traces of the plurality of drive control lines.

(5) A second semiconductor layer is formed. In some examples, a third insulating thin film and a second semiconductor thin film are sequentially deposited on the base substrate on which the aforementioned patterns are formed, and the second semiconductor thin film is patterned through a patterning process to form a third insulating layer and a second semiconductor layer provided on the third insulating layer. In some examples, a material of the second semiconductor layer may include Indium Gallium Zinc Oxide (IGZO). In some examples, the third insulating layer may also be referred to as a third gate insulating layer.

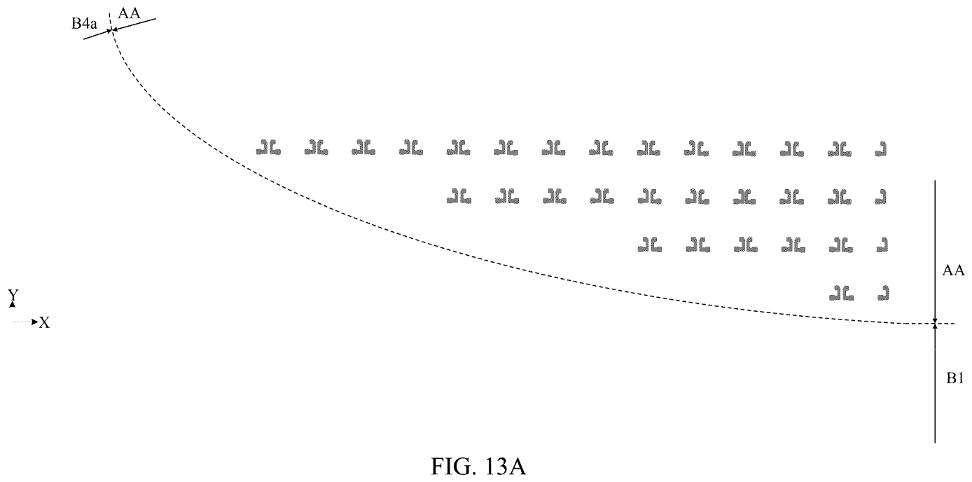

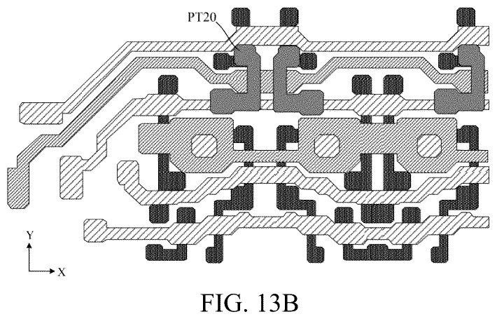

FIG. 13A is a partial schematic diagram of a second semiconductor layer of area C1. FIG. 13B is a partial schematic diagram of a display area after a second semiconductor layer is formed. FIG. 13B illustrates three pixel circuits in a row of sub-pixels closest to the first bezel area after the second semiconductor layer is formed.

In some examples, as shown in FIGS. 13A and 13B, the second semiconductor layer of the display area AA may at least include active layers of second type transistors of the pixel circuit (including, for example, an active layer PT20 of the second pixel transistor). An orthographic projection of the active layer PT20 of the second pixel transistor on the base substrate may be located on a side of an orthographic projection of the active layer PT30 of the third pixel transistor on the base substrate in the second direction Y. The active layer PT20 of the second pixel transistor may be substantially L-shaped. A pattern of a second semiconductor layer of a pixel circuit group may be substantially symmetrical with respect to a center line of the pixel circuit group in the first direction X.

(6) A third conductive layer is formed. In some examples, a fourth insulating thin film and a third conductive thin film are sequentially deposited on the base substrate on which the aforementioned patterns are formed, and the third conductive thin film is patterned through a patterning process to form a fourth insulating layer and a third conductive layer provided on the fourth insulating layer. In some examples, the third conductive layer may also be referred to as a third gate metal layer and the fourth insulating layer may also be referred to as a fourth gate insulating layer.

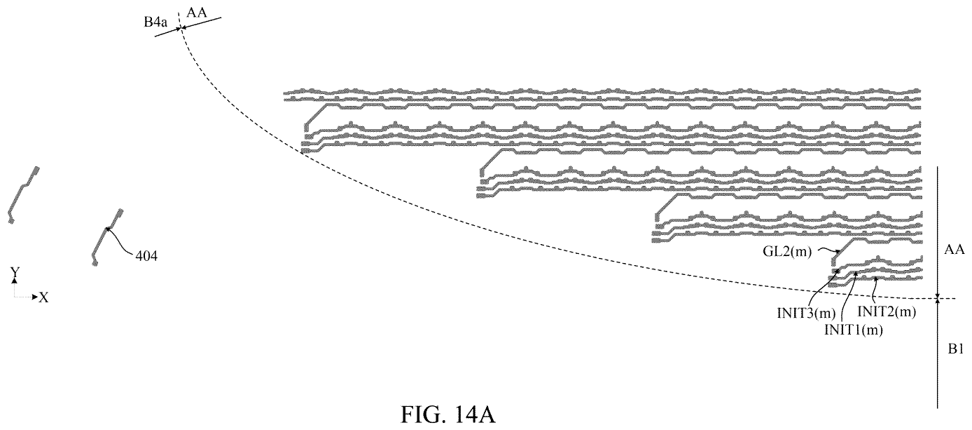

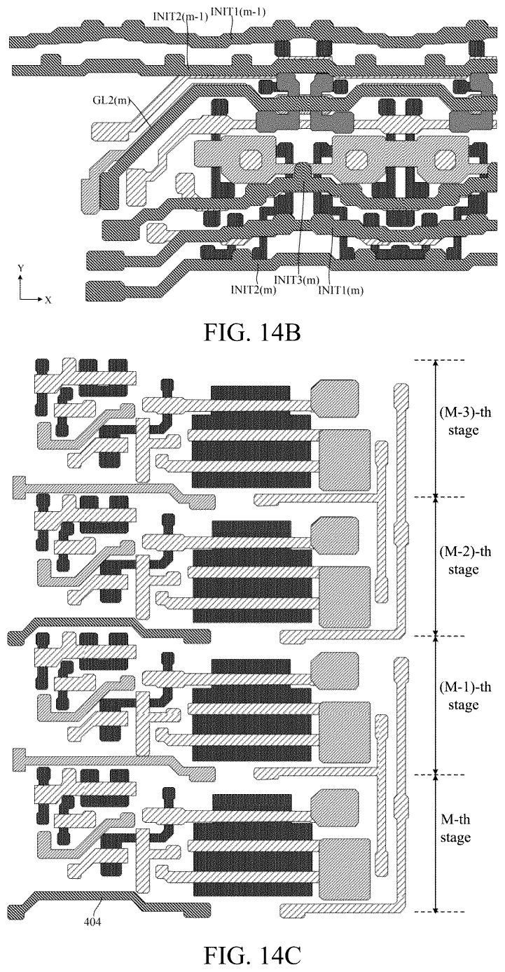

FIG. 14A is a partial schematic diagram of a third conductive layer of area C1. FIG. 14B is a partial schematic diagram of a display area after a third conductive layer is formed. FIG. 14C is a partial schematic diagram of a first corner area after a third conductive layer is formed. FIG. 14B illustrates three pixel circuits in a row of sub-pixels closest to the first bezel area after the first conductive layer is formed. FIG. 14C illustrates four cascaded drive units of the first scan gate drive circuit after the first conductive layer is formed.

In some examples, as shown in FIGS. 14A and 14B, the third conductive layer of the display area AA may at least include a plurality of second scan lines (including, for example, a second scan line GL2(m)), a plurality of first initial signal lines (including, for example, first initial signal lines INIT1(m) and INIT1(m−1)), a plurality of second initial signal lines (including, for example, second initial signal lines INIT2(m) and INIT2(m−1)), and a plurality of third initial signal lines (including, for example, a third initial signal line INIT3(m)).

In some examples, as shown in FIG. 14B, an overlapping region of the second scan line GL2(m) with the active layer PT20 of the second pixel transistor may serve as a gate of the second pixel transistor PT2. An overlapping region of the second auxiliary scan line GL2a(m) with the active layer PT20 of the second pixel transistor may serve as a bottom gate of the second pixel transistor PT2. The second scan line GL2(m) and the second auxiliary scan line GL2a(m) may transmit a same second scan signal.

In some examples, as shown in FIG. 14B, the first initial signal line INIT1(m), the second initial signal line INIT2(m), and the third initial signal line INIT3(m) may be located on a side of the storage capacitors of the M-th row of pixel circuits in the opposite direction of the second direction Y. The first initial signal line INIT1(m) may be located between the second initial signal line INIT2(m) and the third initial signal line INIT3(m). The third initial signal line INIT3(m) may be located on a side of the first initial signal line INIT1(m) in the second direction Y, and the second initial signal line INIT2(m) may be located on a side of the first initial signal line INIT1(m) in the opposite direction of the second direction Y.

In some examples, as shown in FIGS. 14A and 14C, the third conductive layer of the first corner area B4a may at least include a fourth output connection electrode 404. The fourth output connection electrode 404 may be arranged in alignment with a portion where the second output connection electrode 402 is inserted into the two drive units.

(7) A fifth insulating layer is formed. In some examples, a fifth insulating thin film is deposited on the base substrate on which the aforementioned patterns are formed, and the fifth insulating thin film is patterned through a patterning process to form a fifth insulating layer. In some examples, the fifth insulating layer may also be referred to as an interlayer dielectric layer. The fifth insulating layer may be provided with a plurality of vias.

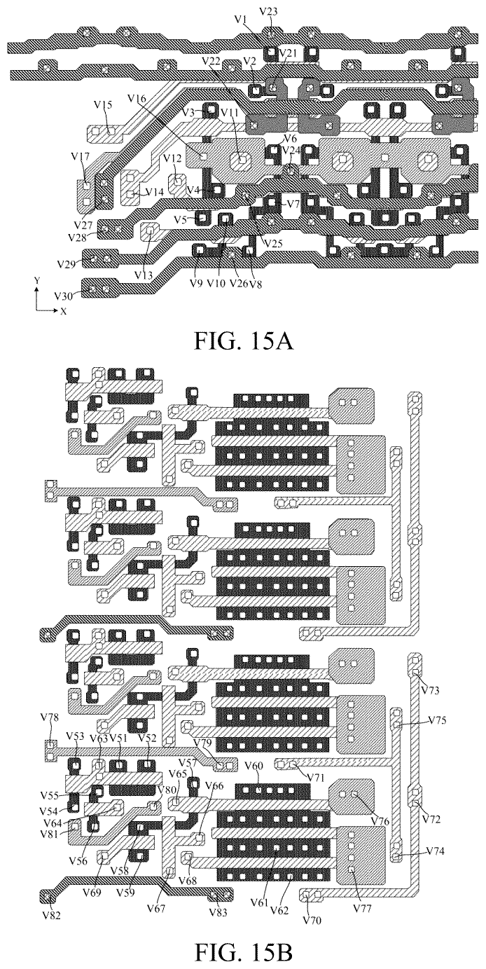

FIG. 15A is a partial schematic diagram of a display area after a fifth insulating layer is formed. FIG. 15B is a partial schematic diagram of a first corner area after a fifth insulating layer is formed.

In some examples, as shown in FIG. 15A, the plurality of vias provided on the fifth insulating layer of the display area may include a first via V1 to a tenth via V10, an eleventh via V11 to a fifteenth via V15, a sixteenth via V16 to a seventeenth via V17, a twenty-first via V21 to a twenty-second via V22, and a twenty-third via V23 to a thirtieth via V30.

In some examples, the fifth insulating layer, the fourth insulating layer, the third insulating layer, the second insulating layer, and the first insulating layer within the first via V1 to the tenth via V10 may be removed, exposing a portion of a surface of the first semiconductor layer. The fifth insulating layer, the fourth insulating layer, the third insulating layer and the second insulating layer within the eleventh via V11 to the fifteenth via V15 may be removed, exposing a portion of a surface of the first conductive layer. The fifth insulating layer, the fourth insulating layers and the third insulating layers within the sixteenth via V16 to the seventeenth via V17 may be removed, exposing a portion of a surface of the second conductive layer. The fifth insulating layer and the fourth insulating layer within the twenty-first via V21 to the twenty-second via V22 may be removed, exposing a portion of a surface of the second semiconductor layer. The fifth insulating layer within the twenty-third via V23 to the thirtieth via V30 may be removed, exposing a portion of a surface of the third conductive layer.

In some examples, as shown in FIG. 15B, the plurality of vias provided by the fifth insulating layer of the first corner area may include a fifty-first via V51 to a sixty-second via V62, a sixty-third via V63 to a seventy-fifth via V75, a seventy-sixth via V76 to an eighty-first via V81, and an eighty-second via V82 to an eighty-third via V83.

In some examples, the fifth insulating layer, the fourth insulating layer, the third insulating layer, the second insulating layer, and the first insulating layer within the fifty-first via V51 to the sixty-second via V62 may be removed, exposing a portion of a surface of the first semiconductor layer. The fifth insulating layer, the fourth insulating layer, the third insulating layer and the second insulating layer within the sixty-third via V63 to the seventy-fifth via V75 may be removed, exposing a portion of a surface of the first conductive layer. The fifth insulating layer, the fourth insulating layers and the third insulating layers within the seventy-sixth via V76 to the eighty-first via V81 may be removed, exposing a portion of a surface of the second conductive layer. The fifth insulating layer within the eighty-second via V82 to the eighty-third via V83 may be removed, exposing a portion of a surface of the third conductive layer.

(8) A fourth conductive layer is formed. In some examples, a fourth conductive thin film is deposited on the base substrate on which the aforementioned patterns are formed, and the fourth insulating thin film is patterned through a patterning process to form a fourth conductive layer on the fifth insulating layer. In some examples, the fourth conductive layer may also be referred to as a first source-drain metal layer.

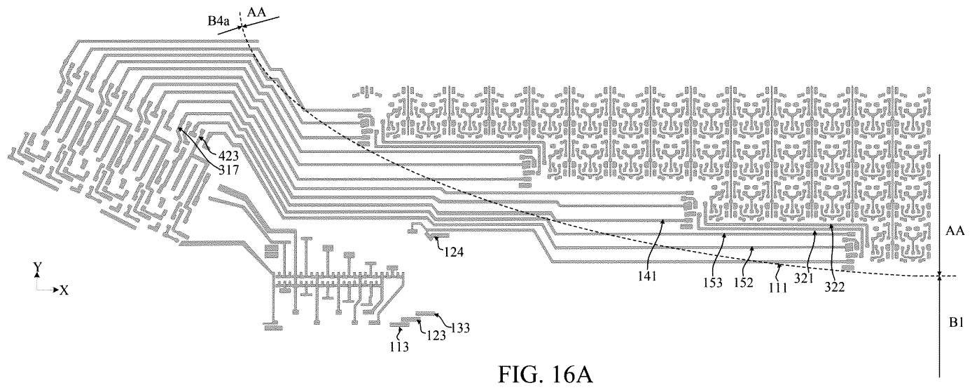

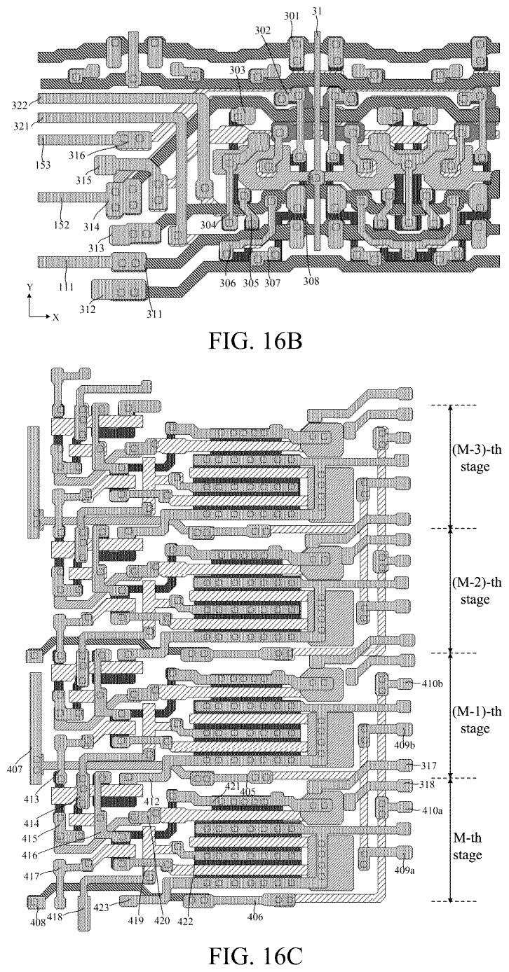

FIG. 16A is a partial schematic diagram of a fourth conductive layer of area C1. FIG. 16B is a partial schematic diagram of a display area after a fourth conductive layer is formed. FIG. 16C is a partial schematic diagram of a first corner area after a fourth conductive layer is formed.

In some examples, as shown in FIGS. 16A and 16B, the fourth conductive layer of the display area AA may at least include a plurality of pixel connection electrodes (including, for example, a first pixel connection electrode 301 to an eighth pixel connection electrode 308), a plurality of trace adapter electrodes (including, for example, s first trace adapter electrode 311 to a sixth trace adapter electrode 316), a third initial auxiliary line 31, a first auxiliary connection line 321, and a second auxiliary connection line 322.

In some examples, the first pixel connection electrode 301 may be connected with the first region of the active layer PT10 of the first pixel transistor PT1 through the first via V1 and may also be connected with the first initial signal line INIT1(m−1) through the twenty-third via V23. The second pixel connection electrode 302 may be connected with the second region of the active layer PT10 of the first pixel transistor PT1 through the second via V2, and may also be connected with the first region of the active layer PT20 of the second pixel transistor PT2 through the twenty-first via V21, and may further be connected with the first region of the active layer PT60 of the sixth pixel transistor PT6 through the sixth via V6. The third pixel connection electrode 303 may be connected with the first region of the active layer PT40 of the fourth pixel transistor PT4 through the third via V3. The fourth pixel connection electrode 304 may be connected with the first region of the active layer PT50 of the fifth pixel transistor PT5 through the fifth via V5, and may also be connected with the second electrode Cst-2 of the storage capacitor through the sixteenth via V16. The fifth pixel connection electrode 305 may be connected with the first region of the active layer PT50 of the fifth pixel transistor PT5 through the fourth via V4, and may also be connected with the second region of the active layer PT80 of the eighth pixel transistor PT8 through the tenth via V10. The sixth pixel connection electrode 306 may be connected with the first region of the active layer PT80 of the eighth pixel transistor PT8 through the ninth via V9, and may also be connected with the third initial signal line INIT3(m) through the twenty-fifth via V25. The seventh pixel connection electrode 307 may be connected with the first region of the active layer PT70 of the seventh pixel transistor PT7 through the eighth via V8, and may also be connected with the second initial signal line INIT2(m) through the twenty-sixth via V26. The eighth pixel connection electrode 308 may be connected with the second region of the active layer PT60 of the sixth pixel transistor PT6 through the seventh via V7.

In some examples, the third initial auxiliary line 31 may be a straight line extending in the second direction Y. The third initial auxiliary line 31 may be connected with the third initial signal line INIT3(m) through the twenty-fourth via V24. The third initial auxiliary line 31 may realize transmission of a third initial signal in the second direction Y, and the third initial auxiliary line 31 and the third initial signal line may form a mesh structure for transmitting the third initial signal in the display area, which is conducive to the transmission uniformity of the third initial signal.

In some examples, the first auxiliary connection line 321 and the second auxiliary connection line 322 may be substantially step-shaped. The second auxiliary connection line 322 may be located on a side of the first auxiliary connection line 321 close to the pixel circuit. The first auxiliary connection line 321 may be configured to connect second reset control lines connected by two adjacent rows of pixel circuits. For example, one end of the first auxiliary connection line 321 may be connected with the second reset control line RST2(m) through the thirteenth via V13, and the other end may be connected with the second reset control line RST2(m−1). In the present example, two adjacent rows of pixel circuits may receive a same second reset control signal as a group.

In some examples, the second auxiliary connection line 322 may be configured to connect light emission control lines connected by two adjacent rows of pixel circuits. For example, one end of the second auxiliary connection line 322 may be connected with the light emitting control line EML(m) through the twelfth via V12, and the other end may be connected with the light emitting control line EML(m−1). In the present example, two adjacent rows of pixel circuits may receive a same light emission control signal as a group.

In some examples, the first trace adapter electrode 311 may be connected with an end of the first initial signal line INIT1(m) through two twenty-ninth vias V29. The first trace adapter electrode 311 and the first sub-connection line 111 of the first adapter line 11 may be of an interconnected integral structure. The first initial signal line INIT1(m) may be connected with a plurality of auxiliary blocks of the display area, and the first initial signal line INIT1(m) may not be connected with a pixel circuit.

In some examples, the second trace adapter electrode 312 may be connected with an end of the second initial signal line INIT2(m) through two thirtieth vias V30. The second trace adapter electrode 311 may be connected with the first sub-connection line 121 of the first adapter line 12 formed subsequently on the fifth conductive layer.

In some examples, the third trace adapter electrode 313 may be connected with an end of the third initial signal line INIT3(m) through two twenty-eighth vias V28. The third trace adapter electrode 313 may be connected with the first sub-connection line 131 of the first adapter line 13 formed subsequently on the fifth conductive layer.

In some examples, the fourth trace adapter electrode 314 may be connected with the second scanning auxiliary line GL2a(m) through two seventeenth vias V17, and may also be connected with the second scanning line GL2(m) through two twenty-seventh vias V27. The fourth trace adapter electrode 314 and the second drive connection line 152 may be of an interconnected integral structure.

In some examples, the fifth trace adapter electrode 315 may be connected with the first scan line GL1(m) through two fourteenth vias V14. The fifth trace adapter electrode 315 and the first drive connection line 151 formed subsequently on the fifth conductive layer may be of an interconnected integral structure.

In some examples, the sixth trace adapter electrode 316 may be connected with the first reset control line RST1(m) through two fifteenth vias V15. The sixth trace adapter electrode 316 and the third drive connection line 153 may be of an interconnected integral structure.

In some examples, as shown in FIGS. 16A and 16C, the fourth conductive layer of the first corner area B4a may at least include a plurality of shift connection electrodes (including, for example, a second shift connection electrode 412 to a thirteenth shift connection electrode 423), a plurality of output connection electrodes (e.g., a fifth output connection electrode 405 to an eighth output connection electrode 408, ninth output connection electrodes 409a and 409b, and tenth output connection electrodes 410a and 410b), a plurality of trace adapter electrodes (including, for example, a seventh trace adapter electrode 317 and an eighth trace adapter electrode 318), a second drive connection line 152, a third drive connection line 153, and a first sub-connection line 111 of the first adapter line 11, and a second adapter line 141.

In some examples, the second shift connection electrode 412 may be connected with the first region of the active layer GT10 of the first shift transistor GT1 through the fifty-second via V52, and may also be connected with an output terminal of a previous-stage drive unit. The third shift connection electrode 413 may be connected with the first region of the active layer GT30 of the third shift transistor GT3 through the fifty-third via V52, and may also be connected with a gate of the eighth shift transistor of the previous-stage drive unit. The fourth shift connection electrode 414 may be connected with an integral structure of gates of the first shift transistor GT1 and the third shift transistor GT3 through the sixty-third via V63, and may also be connected with the first region of the active layer GT20 of the second shift transistor GT2 through the fifty-fifth via V55. The fifth shift connection electrode 415 may be connected with the second region of the active layer GT30 of the third shift transistor GT3 through the fifty-fourth via V54, and may also be connected with the second region of the active layer GT20 of the second shift transistor GT2 through the fifty-sixth via V56, and may further be connected with the first shift connection electrode 411 through the eighty-first via V81. The sixth shift connection electrode 416 may be connected with the second region of the active layer GT10 of the first shift transistor GT1 through the fifty-first via V51, and may also be connected with a gate of the second shift transistor GT2 through the sixty-fourth via V64, and may further be connected with the first region of the active layer GT80 of the eighth shift transistor GT8 through the fifty-eighth via V58. The seventh shift connection electrode 417 may be connected with a gate of the eighth shift transistor GT8 through the sixty-ninth via V69. The eighth shift connection electrode 418 may be connected with a gate of the seventh shift transistor GT7 through the sixty-seventh via V67. The ninth shift connection electrode 419 may be connected with the second region of the active layer GT80 of the eighth shift transistor GT8 through the fifty-ninth via V58, and may also be connected with a gate of the fifth shift transistor GT5 through the sixty-eighth via V68. The tenth shift connection electrode 420 may be connected with the first shift connection electrode 411 through the eightieth via V80, and may also be connected with a gate of the fourth shift transistor GT4 through the sixty-fifth via V65. The eleventh shift connection electrode 421 may be connected with the first region of the active layer GT60 of the sixth shift transistor GT6 through the fifty-seventh via V57, and may also be connected with the first region of the active layer GT40 of the fourth shift transistor GT4 through a plurality of sixtieth vias V60, and may further be connected with the second electrode GC1-2 of the first capacitor through two seventy-sixth vias V76. The twelfth shift connection electrode 422 may be connected with a gate of the seventh shift transistor GT7 through the sixty-sixth via V66, and may also be connected with the first region of the active layer GT50 of the fifth shift transistor GT5 through a plurality of sixty-first vias V6. The thirteenth shift connection electrode 423 may be connected with the second region of the active layer GT50 of the fifth shift transistor GT5 through a plurality of sixty-second vias V62, and may also be connected with the second electrode GC2-2 of the second capacitor through a plurality of seventy-seventh vias V77. The thirteenth shift connection electrode 423 may serve as an output terminal of the current-stage drive unit, and an end portion of the thirteenth shift connection electrode 423 may be located between a ninth output connection electrode and a tenth output connection electrode (e.g., between the ninth output connection electrode 409a and the tenth output connection electrode 410a).

In some examples, the fifth output connection electrode 405 may be connected with the third output connection electrode 403 through the seventy-ninth via V79, and may also be connected with the first output connection electrode 401 through the seventy-first via V71. The sixth output connection electrode 406 may be connected with the fourth output connection electrode 404 through the eighty-third via V83, and may also be connected with the second output connection electrode 402 through the seventieth via V70. The seventh output connection electrode 407 may be connected with the third output connection electrode 403 through the seventy-eighth via V78. The eighth output connection electrode 408 may be connected with the fourth output connection electrode 404 through the eighty-second via V82. The ninth output connection electrode 409a may be connected with the first output connection electrode 401 through the seventy-fourth via V74, and the ninth output connection electrode 409b may be connected with the first output connection electrode 401 through the seventy-fifth via V73. The tenth output connection electrode 410a may be connected with the second output connection electrode 402 through the seventy-second via V72, and the tenth output connection electrode 410b may be connected with the second output connection electrode 402 through the seventy-third via V73.

In some examples, the seventh output connection electrode 407 may be connected with an output terminal of the drive unit of the second scan gate drive circuit. The seventh output connection electrode 407, the third output connection electrode 403, the fifth output connection electrode 405, the first output connection electrode 401, and the ninth output connection electrode 409a (or 409b) are sequentially connected to form a transmission path of the second scan signal. The ninth output connection electrode 409a may be connected with the second drive connection line 152, and configured to, for example, provide a second scan signal to the m-th row of pixel circuits, and the ninth output connection electrode 409b may be connected with another second drive connection line 152, and configured to, for example, provide a second scan signal to the (M−1)-th row of pixel circuits. In the present example, the second scan signal output by one stage of drive unit of the second scan gate drive circuit may be supplied to two rows of pixel circuits.

In some examples, the eighth output connection electrode 408 may be connected with an output terminal of the drive unit of the first reset gate drive circuit. The eighth output connection electrode 408, the fourth output connection electrode 404, the sixth output connection electrode 406, the second output connection electrode 402, and the tenth output connection electrode 410a (or 410b) are sequentially connected to form a transmission path of the first reset control signal. The tenth output connection electrode 410a may be connected with the third drive connection line 153, and configured to, for example, provide a first reset control signal to the m-th row of pixel circuits, and the tenth output connection electrode 410b may be connected with another third drive connection line 153, and configured to, for example, provide a first reset control signal to the (M−1)-th row of pixel circuits. In the present example, the first reset control signal output by one stage of drive unit of the first reset gate drive circuit may be supplied to two rows of pixel circuits.

In some examples, the seventh trace adapter electrode 317 and the eighth trace adapter electrode 318 may be adjacent. A seventh trace adapter electrode 317 and an eighth trace adapter electrode 318 may be located as a group between a tenth output connection electrode and a ninth output connection electrode adjacent thereto (e.g., between the ninth output connection electrode 409b and the tenth output connection electrode 410a).

In some examples, the first initial signal line INIT1(m−1) may be connected with the second adapter line 141, and the second adapter line 141 and the seventh trace adapter electrode 317 may be of an interconnected integral structure, so as to facilitate electrical connection with the fourth initial power supply line INIT1a formed subsequently.

In some examples, one end of the first sub-connection line 111 of the first adapter line 11 may extend to be connected with the first trace adapter electrode 311. For example, the first sub-connection line 111 and the first trace adapter electrode 311 may be of an interconnected integral structure.

In some examples, one end of the second drive connection line 152 may be connected with the fourth trace adapter electrode 314 to realize electrical connection with the second scan line GL2(m) and the second scan assist line GL2a(m). For example, the second drive connection line 152 and the fourth trace adapter electrode 314 may be of an interconnected integral structure. The other end of the second drive connection line 152 may be connected with the ninth output connection electrode 409a to realize connection with the second scan gate drive circuit. For example, the second drive connection line 152 and the ninth output connection electrode 409a may be of an interconnected integral structure.

In some examples, one end of the third drive connection line 153 may be connected with the sixth trace adapter electrode 316 to realize connection with the first reset control line RST1 (m). For example, the third drive connection line 153 and the sixth trace adapter electrode 316 may be of an interconnected integral structure. The other end of the third drive connection line 153 may be connected with the tenth output connection electrode 410a to realize connection with the first reset gate drive circuit. For example, the third drive connection line 153 and the tenth output connection electrode 410a may be of an interconnected integral structure.

In some examples, as shown in FIG. 16A, the fourth conductive layer of the first bezel area B1 may at least include a first connection electrode 113, a second connection electrode 123, and a third connection electrode 133, and a plurality of discharge connection electrodes. The discharge connection electrode may be configured to connect the drive control lines with corresponding electrostatic discharge circuits. The first connection electrode 113 may be configured to connect the second sub-connection line 112 with the first sub-trace INIT1a-1 and the second sub-trace INIT1a-2 of the first initial power supply line INIT1a; the second connection electrode 123 may be configured to connect the second sub-connection line 122 with the first sub-trace INIT2a-1 and the second sub-trace INIT2a-2 of the second initial power supply line INIT2a; and the third connection electrode 133 may be configured to connect the second sub-connection line 132 with the first sub-trace INIT3a-1 and the second sub-trace INIT3a-2 of the third initial power supply line INIT3a.

(9) A sixth insulating layer and a seventh insulating layer are formed. In some examples, a sixth insulating thin film is deposited on the base substrate on which the aforementioned patterns are formed, and the sixth insulating thin film patterned through a patterning process; subsequently, a seventh insulating thin film is coated and then patterned through a patterning process, to form a seventh insulating layer. In some examples, the sixth insulating layer may also be referred to as a passivation layer and the seventh insulating layer may also be referred to as a first planarization layer.

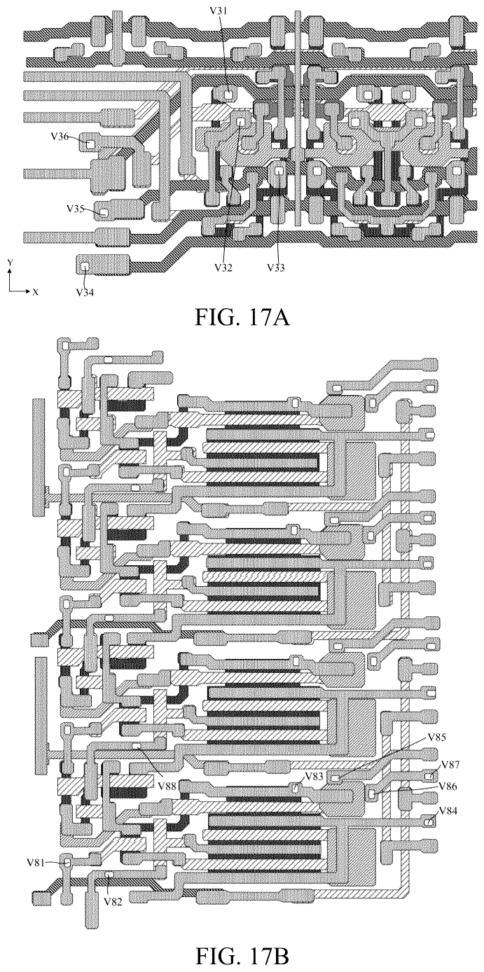

FIG. 17A is a partial schematic diagram of a display area after a seventh insulating layer is formed. FIG. 17B is a partial schematic diagram of a first corner area after a seventh insulating layer is formed.

In some examples, as shown in FIG. 17A, a plurality of vias may be provided on the seventh insulating layer of the display area, which may include, for example, a thirty-first via V31 to a thirty-sixth via V36. The seventh insulating layer and the sixth insulating layer within the thirty-first via V31 to the thirty-sixth via V36 may be removed, exposing a portion of a surface of the fourth conductive layer.

In some examples, as shown in FIG. 17B, a plurality of vias may be provided on the seventh insulating layer of the first corner area, which may include, for example, an eighty-first via V81 to an eighty-seventh via V87. The seventh insulating layer and the sixth insulating layer within the eighty-first via V81 to the eighty-seventh via V87 may be removed, exposing a portion of a surface of the fourth conductive layer.

(10) A fifth conductive layer is formed. In some examples, a fifth conductive thin film is deposited on the base substrate on which the aforementioned patterns are formed, and the fifth conductive thin film is patterned through a patterning process to form a fifth conductive layer on the seventh insulating layer. In some examples, the fifth conductive layer may also be referred to as a second source-drain metal layer.

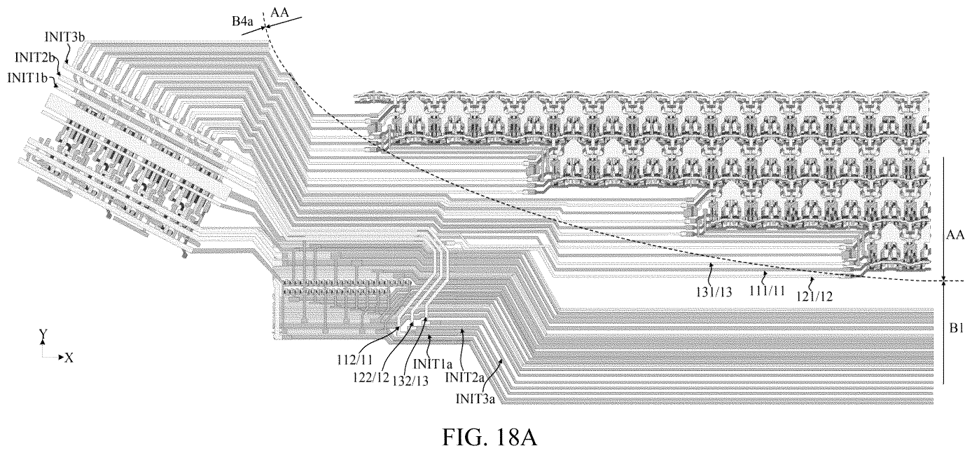

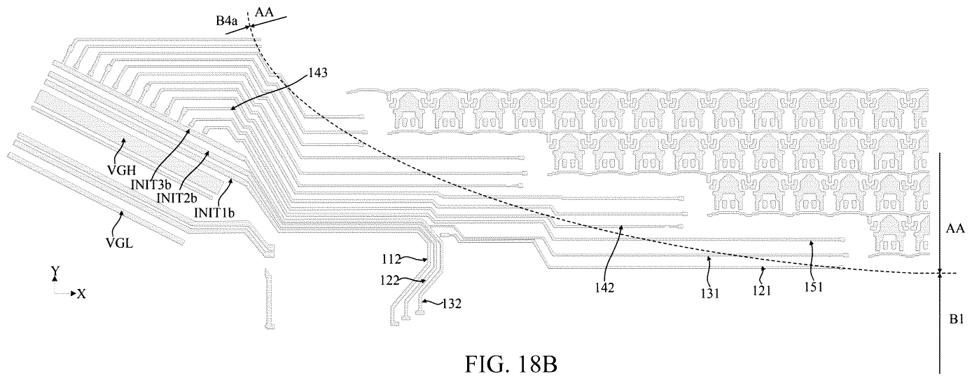

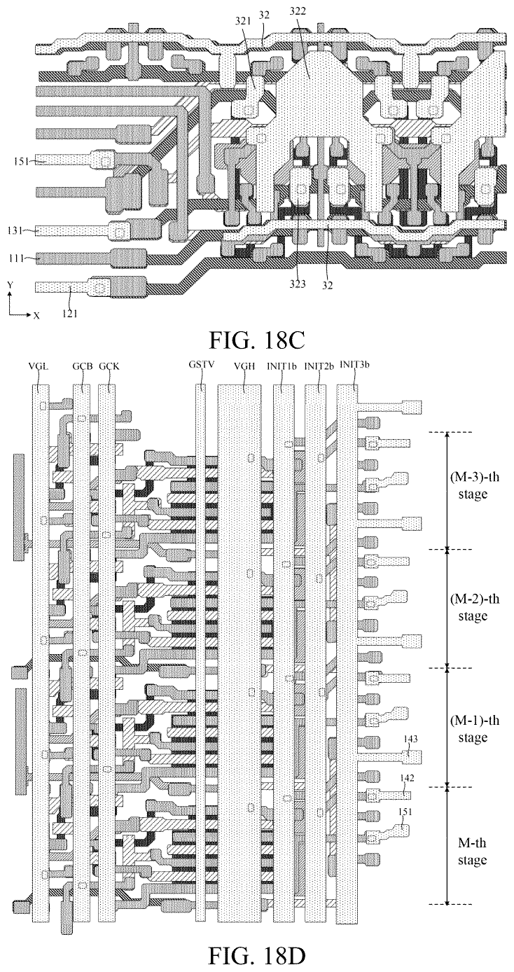

FIG. 18A is a partial schematic diagram of area C1 after a fifth conductive layer is formed. FIG. 18B is a schematic diagram of the fifth conductive layer in FIG. 18A. FIG. 18C is a partial schematic diagram of a display area after a fifth conductive layer is formed. FIG. 18D is a partial schematic diagram of a first corner area after a fifth conductive layer is formed.

In some examples, as shown in FIGS. 18A, 18B and 18C, the fifth conductive layer of the display area AA may at least include a data connection electrode 321, a first power supply connection electrode 322, a first anode connection electrode 323, and a second power supply auxiliary line 32.

In some examples, the data connection electrode 321 may be connected with the third pixel connection electrode 303 through the thirty-first via V31 to realize connection with the first region of the active layer PT40 of the fourth pixel transistor PT4 of the pixel circuit.

In some examples, the first power supply connection electrode 322 may be connected with the fourth pixel connection electrode 304 through the thirty-second via V32 to realize connection with the first region of the active layer PT50 of the fifth pixel transistor PT5 of the pixel circuit and the second electrode Cst-2 of the storage capacitor. First power supply connection electrodes 322 connected by adjacent pixel circuits in adjacent pixel circuit groups may be of an interconnected integral structure, and may be substantially symmetrical with respect to a center line of the two adjacent pixel circuit groups in the first direction X.

In some examples, the first anode connection electrode 323 may be connected with the second region of the active layer PT60 of the sixth pixel transistor PT6 through the thirty-third via V33.

In some examples, the second power supply auxiliary line 32 may extend substantially in the first direction X. An orthographic projection of the second power supply auxiliary line 32 on the base substrate may at least partially overlapped with an orthographic projection of the first initial signal line on the base substrate. The second power supply auxiliary line 32 may be electrically connected with the second power supply line formed subsequently.

In some examples, as shown in FIGS. 18A, 18B and 18D, the fifth conductive layer of the first corner area B4a may at least include a third power supply line VGH, a fourth power supply line VGL, a first clock signal line GCK, a second clock signal line GCB, a first start signal line GSTV, a fourth initial power supply line INIT1b, a fifth initial power supply line INIT2b, a sixth initial power supply line INIT3b, a first drive connection line 151, second adapter lines 142 and 143, a first sub-connection line 121 of the first adapter line 12, and a first sub-connection line 131 of the first adapter line 13. In some examples, the fifth conductive layer of the first bezel area B1 may at least include a second sub-connection line 112 of the first adapter line 11, a second sub-connection line 122 of the first adapter line 12, and a second sub-connection line 132 of the first adapter line 13.

In some examples, the third power supply line VGH may be connected with the eleventh shift connection electrode 421 through the eighty-third via V83 to realize electrical connection with the sixth shift transistor GT6, the fourth shift transistor GT4, and the first capacitor GC1. The third power supply line VGH may be electrically connected with the third power supply line S_VGH in the first bezel area.

In some examples, the fourth power supply line VGL may be connected with the seventh shift connection electrode 417 through the eighty-first via V81 to realize electrical connection with the eighth shift transistor GT8, and the fourth power supply line VGL may also be connected with the third shift connection electrode 413 to realize electrical connection with the third shift transistor GT3 of the current stage and the eighth shift transistor of the previous-stage drive unit. The fourth power supply line VGL may be electrically connected with the fourth power supply line S_VGL in the first bezel area.

In some examples, the first clock signal line GCK may be connected with the fourth shift connection electrode 414 through the eighty-eighth via V88 to realize electrical connection with the first shift transistor GT1, the third shift transistor GT3, and the second shift transistor GT2 of the current-stage drive unit and the seventh shift transistor of the previous-stage drive unit. The second clock signal line GCB may be connected with the eighth shift connection electrode 418 through the eighty-second via V82 to realize electrical connection with the seventh shift transistor of the current-stage drive unit. In some examples, the first shift transistor, the second shift transistor, and the third shift transistor of a (2n−1)-th-stage drive unit may be connected with the first clock signal line GCK, and the seventh shift transistor and the eighth shift transistor may be connected with the second clock signal line GCB. The first shift transistor, the second shift transistor, and the third shift transistor of a 2n-th-stage drive unit may be connected with the second clock signal line GCB, and the seventh shift transistor and the eighth shift transistor may be connected with the first clock signal line GCK. Herein, n may be a positive integer. The present embodiment is not limited thereto.

In some examples, the fourth initial power supply line INIT1b, the fifth initial power supply line INIT2b, and the sixth initial power supply line INIT3b may be arranged sequentially in a direction close to the display area. The fourth initial power supply line INIT1b, the fifth initial power supply line INIT2b, and the sixth initial power supply line INIT3b may be located on a side of the fourth power supply line VGH close to the display area. Orthographic projections of the fourth initial power supply line INIT1b, the fifth initial power supply line INIT2b, and the sixth initial power supply line INIT3b on the base substrate may be at least partially overlapped with an orthographic projections of the first scan gate drive circuit on the base substrate. For example, the orthographic projections of the fourth initial power supply line INIT1b and the fifth initial power supply line INIT2b on the base substrate may be partially overlapped with orthographic projections of the first capacitor and the second capacitor of the drive unit of the first scan gate drive circuit on the base substrate. The manner of arrangement in the present example may reduce the trace arrangement space, which is conducive to the narrow bezel design.

In some examples, the fourth initial power supply line INIT1b may be connected with the seventh trace adapter electrode 317 through the eighty-fifth via V85. The seventh trace adapter electrode 317 and the second adapter line 141 located on the fourth conductive layer may be of an interconnected integral structure. The fourth initial power supply line INIT1b and the second sub-connection line 112 may be of an interconnected integral structure.

In some examples, the fifth initial power supply line INIT2b may be connected with the eighth trace adapter electrode 318 located on the fourth conductive layer through the eighty-sixth via V86. The eighth trace adapter electrode 318 may be connected with the second adapter line 142 located on the fifth conductive layer through the eighty-seventh via V87. The second adapter line 142 may be connected with the second initial signal line connected by the (M−1)-th row of pixel circuits to realize transmission of the second initial signal. The fifth initial power supply line INIT2b and the second sub-connection line 122 may be of an interconnected integral structure.

In some examples, the sixth initial power supply line INIT3b and the third adapter line 143 may be of an interconnected integral structure. The third adapter line 143 may be connected with the third initial signal line connected by the (M−1)-th row of pixel circuits to realize transmission of the third initial signal. The sixth initial power supply line INIT3b and the second sub-connection line 132 may be of an interconnected integral structure.

In some examples, one end of the first drive connection line 151 may be connected with the fifth trace adapter electrode 315 through the thirty-sixth via V36 to achieve connection with the first scan line GL1(m). The first drive connection line 151 may be connected with the thirteenth shift connection electrode 423 of the M-th-stage drive unit through the eighty-fourth via V84 to realize transmission of the first scan signal.

In some examples, the first sub-connection line 121 of the first adapter line 12 may be connected with the first trace adapter electrode 311 through the thirty-fourth via V34. The first sub-connection line 121 may be connected with the second sub-connection line 122 located on the fifth conductive layer through the fourth connection electrode 124 located on the fourth conductive layer.

In some examples, the first sub-connection line 131 of the first adapter line 13 may be connected with the third trace adapter electrode 313 through the thirty-fifth via V35. The first sub-connection line 131 and the second sub-connection line 132 of the first adapter line 13 may be of an interconnected integral structure. In the present example, the fourth initial power supply line INIT1b may be connected with the first initial power supply line INIT1a through the second sub-connection line 112 of the first adapter line 11; the fifth initial power supply line INIT2b may be connected with the second initial power supply line INIT2a through the second sub-connection line 122 of the first adapter line 12; and the sixth initial power supply line INIT3b may be connected with the third initial power supply line INIT3a through the second sub-connection line 132 of the first adapter line 13. However, the present embodiment is not limited thereto. In some other examples, the fourth initial power supply line, the fifth initial power supply line, and the sixth initial power supply line may be connected with corresponding initial power supply lines in the first bezel area through remaining connection lines.

In the present example, the first scan line connected by each row of pixel circuits may be connected with an output terminal of a drive unit of the first scan gate drive circuit through the first drive connection line 151 located on the fifth conductive layer; the second scan line and the second scan auxiliary line connected by each row of the pixel circuits may be connected with an output terminal of a drive unit of the second scan gate drive circuit through the second drive connection line 152 located on the fourth conductive layer; and the first reset control suction connected by each row of pixel circuits may be connected with an output terminal of a drive unit of the first reset gate drive circuit through the third drive connection line 153 located on the fourth conductive layer. The first drive connection line 151 connected by each row of pixel circuits may be located between the second drive connection line 152 and the third drive connection line 153. Orthographic projections of the first drive connection line 151, the second drive connection line 152, and the third drive connection line 153 on the base substrate may be not overlapped with each other.

In the present example, a second initial signal line connected by the last row of pixel circuits is connected with a first sub-connection line 121 located on the fifth conductive layer, and a third initial signal line connected by the last row of pixel circuits is connected with a first sub-connection line 131 located on the fifth conductive layer. A first initial signal line closest to the first bezel area is connected with the first sub-connection line 111 located on the fourth conductive layer. The first sub-connection line 111 may be located between the first sub-connection line 121 and the first sub-connection line 131. Remaining first initial signal lines may be connected with corresponding second adapter lines 141 located on the fourth conductive layer, remaining second initial signal lines may be connected with corresponding second adapter lines 142 located on the fifth conductive layer, and remaining third initial signal lines may be connected with corresponding second adapter lines 143 located on the fifth conductive layer. The second adapter line 141 may be located between the second adapter line 142 and the second adapter line 143. Orthographic projections of the first sub-connection lines 111, 121 and 131 on the base substrate may not be overlapped with orthographic projections of the second adapter lines 141, 142 and 143 on the base substrate.

In the present example, by providing that the plurality of traces in the first corner area are arranged at intervals between the fifth conductive layer and the fourth conductive layer, it is conducive to reducing a space between adjacent traces and reducing an arrangement space required for traces, thereby supporting the realization of narrow bezel design.

(10) An eighth insulating layer is formed. In some examples, an eighth insulating thin film is coated on the base substrate on which the aforementioned patterns are formed, and the eighth insulating thin film is patterned through a patterning process to form an eighth insulating layer. In some examples, the eighth insulating layer may also be referred to as a second planarization layer.

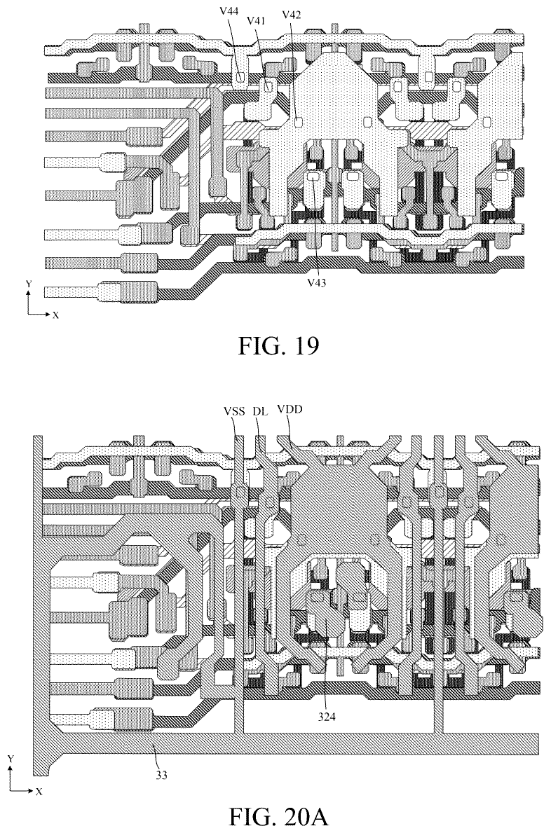

FIG. 19 is a partial schematic diagram of a display area after an eighth insulating layer is formed. In some examples, as shown in FIG. 19, a plurality of vias may be provided on the eighth insulating layer of the display area, which may include, for example, a forty-first via V41 to a forty-fourth via V44. The eighth insulating layer in the forty-first via V41 to the forty-fourth via V44 may be removed, exposing a portion of a surface of the fifth conductive layer.

(11) A sixth conductive layer is formed. In some examples, a sixth conductive thin film is deposited on the base substrate on which the aforementioned patterns are formed, and the sixth conductive thin film is patterned through a patterning process to form a sixth conductive layer on the eighth insulating layer. In some examples, the sixth conductive layer may also be referred to as a third source-drain metal layer.

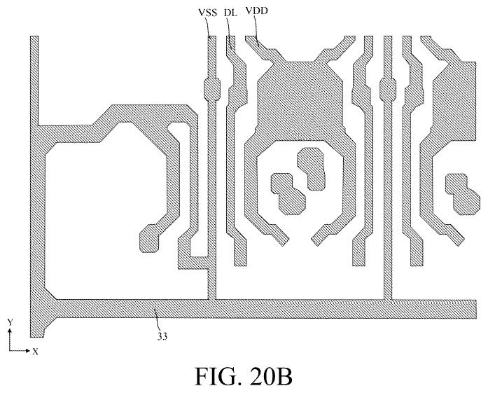

FIG. 20A is a partial schematic diagram of a display area after a sixth conductive layer is formed. FIG. 20B is a schematic diagram of the sixth conductive layer in FIG. 20A.

In some examples, as shown in FIGS. 20A and 20B, the sixth conductive layer of the display area may at least include a data line DL, a first power supply line VDD, a second anode connection electrode 324, and a second power supply line VSS.

In some examples, the data line DL may have a bend line shape extending substantially in the second direction Y. The data line DL may be connected with the data connection electrode 321 through the forty-fourth via V44 to provide a data signal to the fourth pixel transistor PT4 of the pixel circuit.

In some examples, the second anode connection electrode 324 may be connected with the first anode connection electrode 323 through the forty-third via V43 to achieve connection with the second electrode of the sixth pixel transistor PT4 of the pixel circuit.

In some examples, the first power supply line VDD may have a non-uniform width linear shape extending substantially in the second direction Y. The first power supply line VDD may be connected with the first power supply connection electrode 322 through the forty-second via V42 to realize transmission of the first voltage signal in the second direction Y. The first power supply line VDD connected by adjacent two pixel circuits may be of an interconnected integral structure, and the integral structure may be substantially symmetrical with respect to a center line of the two pixel circuits in the first direction X. The first power supply line VDD may be connected with an integral structure of second electrodes of a plurality of storage capacitors located on the second conductive layer through the first power supply connection electrode 322, to realize a mesh structure for transmitting the first voltage signal in the display area, which is conducive to the transmission uniformity of the first voltage signal.

In some examples, the second power supply line VSS may be connected with the second power supply auxiliary line 32 through the forty-fourth via V44. The second power supply line VSS and the second power supply auxiliary line 32 may be connected in the display area to form a mesh structure for transmitting the second voltage signal, which is conducive to the transmission uniformity of the second voltage signal.

In some examples, the sixth conductive layer of the peripheral area may at least include a second voltage transmission structure 33. The second voltage transmission structure 33 may be in a mesh shape, and may be of an interconnected integral structure with the second power supply line VSS of the display area.

In some examples, the second voltage supply line S_VSS of the peripheral area may be a three-layer trace structure, which may include, for example, a first sub-power supply line located on the fourth conductive layer, a second sub-power supply line located on the fifth conductive layer, and a third sub-power supply line located on the sixth conductive layer. The third sub-power supply line and the second voltage transmission structure 33 may be an interconnected integral structure.

In some examples, a ninth insulating layer may be formed after the sixth conductive layer is formed. So far, the preparation of a circuit structure layer of the display substrate is completed. Subsequently, a light emitting structure and an encapsulation structure layer may be formed in sequence.

In some examples, the first conductive layer, the second conductive layer, the third conductive layer, the fourth conductive layer, the fifth conductive layer, and the sixth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulating layer, the second insulating layer, the third insulating layer, the fourth insulating layer, the fifth insulating layer, and the sixth insulating layer may be made of any one or more of Silicon Oxide (SiOx, x>0), Silicon Nitride (SiNy, y>0), and Silicon OxyNitride (SiON), and may be a single layer, a multi-layer, or a composite layer. The seventh insulating layer to the ninth insulating layer may be made of an organic material, such as polyimide, acrylic, or polyethylene terephthalate. However, the present embodiment is not limited thereto.

A structure and a preparation process of the display substrate of the embodiment are merely illustrative. In some examples, a corresponding structure may be changed and a patterning process may be added or reduced according to actual needs. In other examples, a bottom metal shielding layer (BSM) may be provided on a side of the first semiconductor layer close to the base substrate, a first buffer layer may be provided between the bottom metal shielding layer and the base substrate, a second buffer layer may be provided between the bottom metal shielding layer and the first semiconductor layer, and an orthographic projection of the bottom metal shielding layer on the base substrate may cover channel regions of active layers of a plurality of first type transistors of the pixel circuit, to improve the performance of the first type transistors of the pixel circuit. However, the present embodiment is not limited thereto. In some other examples, the sixth conductive layer may be omitted and the data line and the first power supply line may be provided on the fifth conductive layer.

The preparation process of the present exemplary embodiment may be implemented using an existing mature manufacturing device, and may be compatible well with an existing manufacturing process, simple in process implementation, easy to implement, high in a production efficiency, low in a production cost, and high in yield.

According to the display substrate provided the present example, the second initial signal line and the third initial signal line connected by the M-th row of pixel circuits are connected with the second initial power supply line and the third initial power supply line of the first bezel area respectively through the first adapter line (including the first sub-connection line and the second sub-connection), and the first initial signal line closest to the first bezel area is connected with the first initial power supply line of the first bezel area, which may reduce a quantity of traces extending to the first gate drive circuit in the first corner area, ensure normal connection of the a plurality of rows of pixel circuits close to the arc-shaped display area, and facilitate the narrow bezel design.

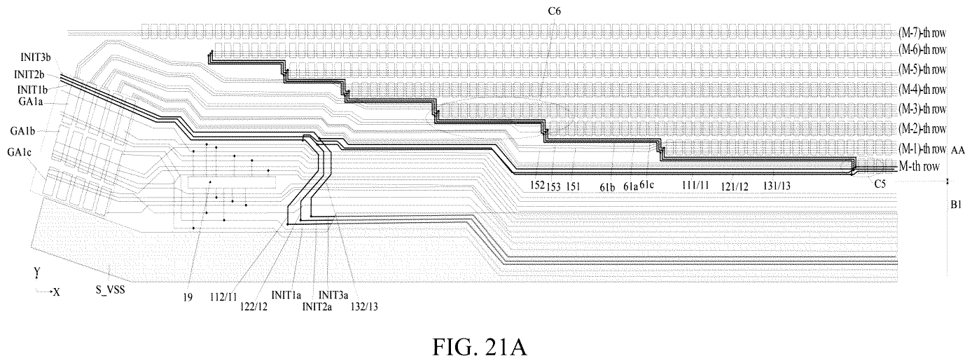

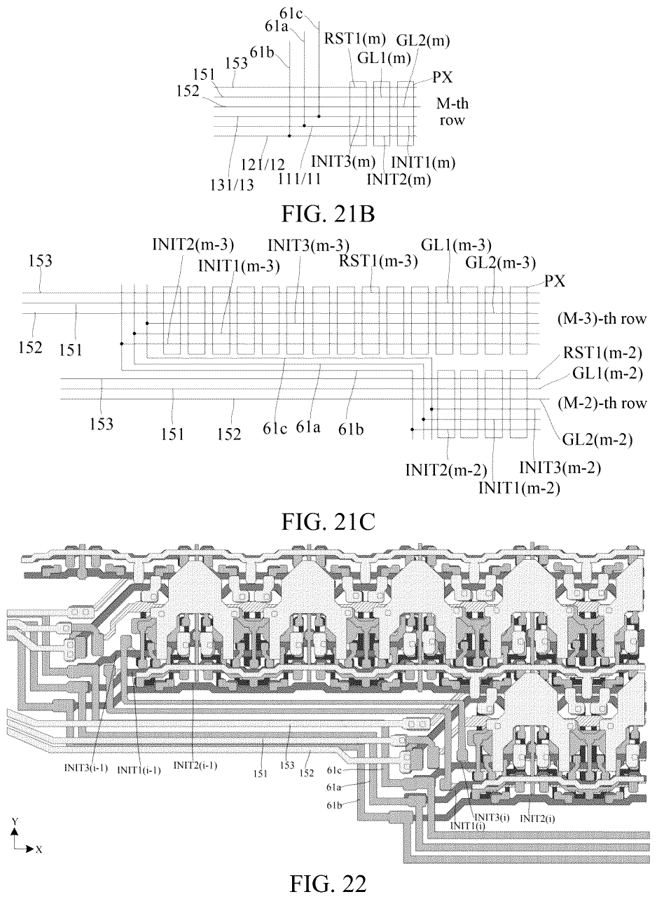

FIG. 21A is a schematic diagram of another partial structure of area C1 in FIG. 1. FIG. 21B is a schematic diagram of partial line connection in area C5 of FIG. 21A. FIG. 21C is a schematic diagram of partial line connection in area C6 of FIG. 21A. FIG. 21A is illustrated with an example of eight rows of sub-pixels (e.g., a (M−7)-th row to an M-th row of sub-pixels) close to the arc-shaped display boundary of the display area AA, where the M-th row of sub-pixels may be closest to the first bezel area B1, and M may be a positive integer. The M-th row of sub-pixels may be a last row of sub-pixels on the display substrate.

In some examples, as shown in FIGS. 21A to 21C, pixel circuits of each row of sub-pixels may be electrically connected with three constant voltage signal lines (including, for example, a first initial signal line INIT1, a second initial signal line INIT2, and a third initial signal line INIT3). At least one constant voltage signal line connected by pixel circuits of K rows of sub-pixels (e.g., K is 7, including the M-th to the (M−6)-th rows of sub-pixels) close to the first bezel area B1 may be connected with a first area constant voltage power supply line located in the first bezel area B1 through a first adapter line.

In some examples, as shown in FIGS. 21A to 21C, constant voltage signal lines transmitting a same signal and connected by pixel circuits of seven rows of sub-pixels closest to the first bezel area B1 may be connected through a series connection line and connected with a first area constant voltage power supply line of the first bezel area B1 by a first adapter line. For example, first initial signal lines connected by pixel circuits of adjacent rows of pixel circuits in the M-th to (M−6)-th rows may be connected through a first series connection line 61a, and connected with the first adapter line 11 through the first initial signal line closest to the first bezel area B1, and the first adapter line 11 is connected with the first initial power supply line INIT1a of the first bezel area B1. Second initial signal lines connected by pixel circuits of adjacent rows of pixel circuits in the M-th to (M−6)-th rows may be connected through a second series connection line 61b, and connected with the first adapter line 12 through the second initial signal line closest to the first bezel area B1, and the first adapter line 12 is connected with the second initial power supply line INIT2a of the first bezel area B1. Third initial signal lines connected by pixel circuits of adjacent rows of pixel circuits in the M-th to (M−6)-th rows may be connected through a third series connection line 61c, and connected with the first adapter line 13 through the third initial signal line closest to the first bezel area B1, and the first adapter line 13 is connected with the third initial power supply line INIT3a of the first bezel area B1. For example, the first initial signal lines INIT1(m−3) and INIT1(m−2) may be connected with the first initial signal line INIT1(m) through the first series connection line 61a, and the first initial signal line INIT1(m) may be connected with the first sub-connection line 111 of the first adapter line 11. The second initial signal lines INIT2 (m−3) and INIT2(m−2) may be connected with the second initial signal line INIT2(m) through the second series connection line 61b, and the second initial signal line INIT2(m) may be connected with the first sub-connection line 121 of the first adapter line 12. The third initial signal lines INIT3 (m−3) and INIT3(m−2) may be connected with the third initial signal line INIT3(m) through the third series connection line 61c, and the third initial signal line INIT3(m) may be connected with the first sub-connection line 131 of the first adapter line 13.

In some examples, the first series connection line 61a, the second series connection line 61b, and the third series connection line 61c may extend in a stepped shape formed by adjacent rows of pixel circuits. The second series connection line 61b, the first series connection line 61a, and the third series connection line 61c may be arranged sequentially in a direction close to the pixel circuit.

In some examples, the first initial signal line, the second initial signal line, and the third initial signal line connected by the seven rows of pixel circuits closest to the first bezel area B1 are connected with the first initial power supply line, the second initial power supply line, and the third initial power supply line of the first bezel area, respectively, through the first adapter line, so that a quantity of traces in the first corner area may be reduced. In the present example, each row of pixel circuits has three signal lines (including, for example, a first drive connection line 151 connected by a first scan line, a second drive connection line 152 connected by a second scan line, and a third drive connection line 153 connected by a first reset control line) connected to a gate drive circuit. Compared with each row of pixel circuits having six signal lines (including, for example, a first drive connection line 151 connected by a first scan line, a second drive connection line 152 connected by a second scan line, a third drive connection line 153 connected by a first reset control line, and three second adapter lines) extending to the gate drive circuit, the present example may reduce a quantity of traces from an area where the gate drive circuit is located to the display area in the first corner area. For example, a line connection space may be saved by 7*4.2*3=88.2 μm, and a space utilization rate may be increased by 50%. In the present example, by reducing a quantity of connections, the cut-off position of the gate drive circuit may be continuously moved up, which is conducive to widening a line width of the second power supply line S_VSS, thereby preventing excessive resistance and current density, and reducing power consumption. Moreover, Dummy Pixels in the display area may be retained to ensure etching uniformity and stable transistor characteristics in the display area. The present example is conducive to the realization of a narrow bezel design, and may be conducive to the design of a display product with a larger screen-to-body ratio.

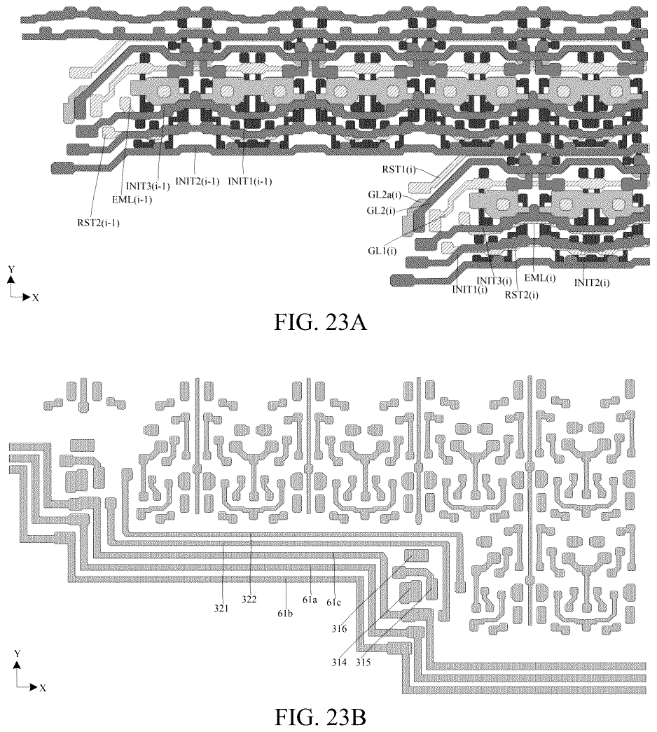

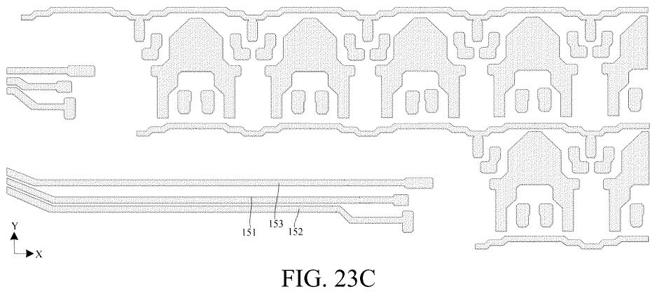

FIG. 22 is a partial schematic diagram of a display area according to at least one embodiment of the present disclosure. FIG. 22 illustrates a trace connection structure between two adjacent rows of pixel circuits (e.g., an i-th row of pixel circuits and an (i−1)-th row of pixel circuits) closest to the first bezel area, where i may be a positive integer less than M. FIG. 22 illustrates a partial schematic diagram of a display substrate after a fifth conductive layer is formed. FIG. 23A is a schematic diagram of a display area after a third conductive layer is formed in FIG. 22. FIG. 23B is a schematic diagram of the fourth conductive layer in FIG. 22. FIG. 23C is a schematic diagram of the fifth conductive layer in FIG. 22.

In some examples, as shown in FIGS. 22 to 23C, first initial signal lines INIT1(i) and INIT1(i−1), second initial signal lines INIT2(i) and INIT2(i−1), and third initial signal lines INIT3(i) and INIT3(i−1) may be located on the third conductive layer. The first initial signal lines INIT1(i) and INIT1(i−1) may be connected through a first series connection line 61a, the second initial signal lines INIT2(i) and INIT2(i−1) may be connected through a second series connection line 61b, and the third initial signal lines INIT3(i) and INIT3(i−1) may be connected through a third series connection line 61c. The first series connection line 61a, the second series connection line 61b, and the third series connection line 61c may be located on the fourth conductive layer. The second series connection line 61b the first series connection line 61a and the third series connection line 61c may be arranged sequentially in a direction close to the pixel circuit. The first series connection line 61a, the second series connection line 61b, and the third series connection line 61c may extend in a stepped shape formed between the i-th row of pixel circuits and the (i−1)-th row of pixel circuits.

In some examples, the fourth conductive layer may further include a first auxiliary connection line 321 and a second auxiliary connection line 322. The first auxiliary connection line 321 may connect second reset control lines RST2(i) and RST2(i−1) located on the first conductive layer. The secondary connection line 322 may connect light emission control lines EML(i) and EML(i−1) located on the first conductive layer. The first auxiliary connection line 321 and the second auxiliary connection line 322 may be located on a side of the three series connection lines close to the pixel circuit. Extending directions of the first auxiliary connection lines 321 and the second auxiliary connection lines 322 may be substantially the same as extending directions of the three series connection lines.

In some examples, the first drive connection line 151, the second drive connection line 152, and the third drive connection line 153 may be located on the fifth conductive layer. The first drive connection line 151 may be connected with the first scan line GL1(i) located on the first conductive layer through the fifth trace adapter electrode 315 located on the fourth conductive layer. The second drive connection line 152 may be connected with the second scan auxiliary line GL2a(i) located on the second conductive layer and the second scan line GL2(i) located on the third conductive layer through the fourth trace adapter electrode 314 located on the fourth conductive layer. The third drive connection line 153 may be connected with the first reset control line RST1(i) located on the first conductive layer through the sixth trace adapter electrode 316 located on the fourth conductive layer. However, the present embodiment is not limited thereto. In some other examples, the fourth trace adapter electrode, the fifth trace adapter electrode, and the sixth trace adapter electrode may be located on the fifth conductive layer, and the first drive connection line, the second drive connection line, and the third drive connection line may be located on the fourth conductive layer.

In the present example, by connecting the initial signal line connected by the seven rows of pixel circuits close to the first bezel area and leading them out to the first bezel area so as to connect the initial power supply line located in the first bezel area, a quantity of traces in the first corner area may be reduced, thereby facilitating the realization of a narrow bezel design. Rest of description of the present example may be referred to description of the aforementioned embodiments, and thus will not be repeated here.

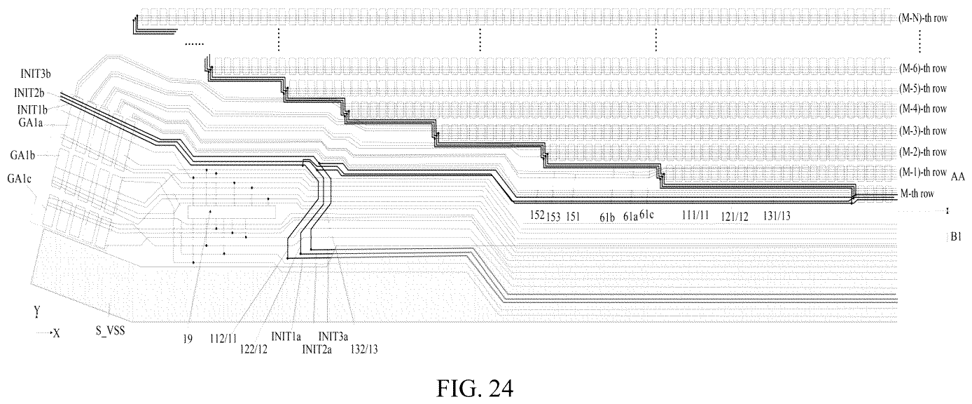

FIG. 24 is a schematic diagram of another partial structure of area C1 in FIG. 1. In some examples, as shown in FIG. 24, the arc-shaped display boundary corresponding to the first corner area may be adjacent to N rows of sub-pixels of the display area, that is, N rows of sub-pixels are close to the arc-shaped display boundary, and N may be a positive integer. Constant voltage signal lines transmitting a same signal and connected by the pixel circuits of the N rows of sub-pixels may be connected together, and are connected with a first area constant voltage power supply line of the first bezel area through a first adapter line. For example, the first initial signal lines corresponding to adjacent rows of pixel circuits among the N rows of pixel circuits may be connected through the first series connection line 61a, and the first initial signal line closest to the first bezel area may be connected with the first initial power supply line INIT1a through the first adapter line 11. Second initial signal lines corresponding to adjacent rows of pixel circuits among the N rows of pixel circuits may be connected through the second series connection line 61b, and the second initial signal line closest to the first bezel area may be connected with the second initial power supply line INIT2a through the first adapter line 12. Third initial signal lines corresponding to adjacent rows of pixel circuits among the N rows of pixel circuits may be connected through the third series connection line 61c, and the third initial signal line closest to the first bezel area may be connected with the third initial power supply line INIT3a through the first adapter line 13.

In some examples, assuming that the first corner area corresponds to 150 rows of sub-pixels, by using a second adapter line that saves three initial signal lines for each row of pixel circuits, that is, a trace space of 4.2*3=12.6 m may be saved in the first corner area for each corresponding row of pixel circuits. In this way, the cut-off position of the gate drive circuit may be moved upwards. For example, the cut-off position of the gate drive circuit may be moved upwards by a quarter of a total length of the first corner area. Alternatively, a line width of the second power supply line S_VSS may be widened, for example, the line width of the second power supply line S_VSS may be doubled. Rest of description of the present example may be referred to description of the aforementioned embodiments, and thus will not be repeated here.

An embodiment further provides a display substrate, including a display area and a peripheral area surrounding the display area. The display area includes at least one segment of an arc-shaped display boundary. The display area includes M rows of sub-pixels provided on a base substrate; at least one row of sub-pixels among the M rows of sub-pixels include a plurality of sub-pixels arranged sequentially in a first direction; at least one sub-pixel includes a pixel circuit and a light emitting element connected with the pixel circuit; and pixel circuits of the at least one row of sub-pixels among the M rows of sub-pixels are connected with at least one constant voltage signal line extending in the first direction. N rows of sub-pixels close to the arc-shaped display boundary are arranged in a stepped manner, where both N and M are positive integers, and N is less than or equal to M. The peripheral area includes a first bezel area located on a side of the display area in a second direction and a first corner area located at a perimeter of the arc-shaped display boundary, and the first bezel area is in communication with the first corner area. The second direction intersects the first direction. The first bezel area includes at least one first area constant voltage power supply line provided on the base substrate. A constant voltage signal line connected by pixel circuits of at least one row of sub-pixels among the N rows of sub-pixels close to the arc-shaped display boundary is connected with the first area constant voltage power supply line of the first bezel area through a first adapter line. A portion of the first adapter line is located in the first corner area.

According to the display substrate provided by the present embodiment, the constant voltage signal line connected by the pixel circuits of the at least one row of sub-pixels among the N rows of sub-pixels close to the arc-shaped display boundary is provided to be connected with the first area constant voltage power supply line of the first bezel area, which may reduce a quantity of traces in the first corner area and ensure normal line connection of a plurality of rows of sub-pixels close to the arc-shaped display boundary, thereby facilitating the narrow bezel design.

In some exemplary embodiments, the first adapter line may include a first sub-connection line and a second sub-connection line, an extension direction of the first sub-connection line intersects with an extension direction of the second sub-connection line, and the first sub-connection line and the second sub-connection line are connected. The first sub-connection line is connected with the constant voltage signal line connected by the pixel circuits of the at least one row of sub-pixels among the N rows of sub-pixels close to the arc-shaped display boundary, and the second sub-connection line is connected with the first area constant voltage power supply line. A connection position of the first sub-connection line and the second sub-connection line may be located in the first corner area. The present example may facilitate the reduction of traces extending to an area where the gate drive circuit is located, thereby facilitating the narrow bezel design.

In some exemplary embodiments, the peripheral area may further include at least one second area constant voltage power supply line extending to the first corner area and connected with the first area constant voltage power supply line through the second sub-connection line. In some exemplary embodiments, the second area constant voltage power supply line and the second sub-connection line connected therewith may be of an interconnected integral structure. The present example may facilitate the connection between the first area constant voltage power supply line and the second area constant voltage power supply line, and may save the required traces.

In some exemplary embodiments, the first corner area may further include a plurality of cascaded drive units provided on the base substrate, the second area constant voltage power supply line is located on a side of the plurality of cascaded drive units close to the display area, and the second sub-connection line may be located on a side of the plurality of drive units close to the first area constant voltage power supply line in the first direction. In some exemplary embodiments, the drive units may be connected with a gate line connected by at least one row of sub-pixels through a drive connection line, and the drive connection line may be located on a side of the first sub-connection line close to the display area in the second direction. The manner of arrangement in the present example may facilitate the reduction of a quantity of traces in the first corner area, thereby facilitating the narrow bezel design.

Relevant description of the display substrate of the present embodiment may refer to the descriptions in the aforementioned embodiments, and thus will not be repeated here.

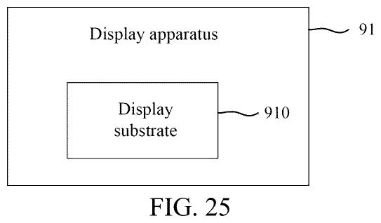

FIG. 25 is a schematic diagram of a display apparatus according to at least one embodiment of the present disclosure. In some examples, as shown in FIG. 25, an embodiment provides a display apparatus, including a display substrate of the aforementioned embodiments.

In some examples, the display substrate 91 may be a flexible OLED display substrate, a QLED display substrate, a Micro-LED display substrate, or a Mini-LED display substrate. The display apparatus may be a product having an image (including a still image or a moving image, wherein the moving image may be a video) display function. For example, the display apparatus may be: displays, televisions, billboards, digital photo frames, laser printers with display function, telephones, mobile phones, picture screens, personal digital assistants (PDA), digital cameras, portable camcorders, viewfinders, navigators, vehicles, large-area walls, information inquiry equipment (such as business inquiry equipment in e-government, banks, hospitals, power departments, etc.), monitors, etc. As another example, the display apparatus may be any one of a micro-display, a VR device including a micro-display, or an AR device.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. It should be noted that the above examples or embodiments are exemplary only and not restrictive. Therefore, the present disclosure is not limited to what is specifically shown and described herein. Various modifications, substitutions or omissions may be made in forms and details of implementation modes without departing from the scope of the present disclosure.

1. A display substrate, comprising a display area and a peripheral area surrounding the display area, wherein the display area comprises at least one segment of an arc-shaped display boundary;
the display area comprises M rows of sub-pixels provided on a base substrate, at least one row of sub-pixels among the M rows of sub-pixels comprise a plurality of sub-pixels arranged sequentially in a first direction, at least one sub-pixel among the plurality of sub-pixels comprises a pixel circuit and a light emitting element connected with the pixel circuit, and pixel circuits of the at least one row of sub-pixels among the M rows of sub-pixels are connected with at least one constant voltage signal line extending in the first direction; and N rows of sub-pixels close to the arc-shaped display boundary are arranged in a stepped manner, where both N and M are positive integers, and N is less than or equal to M;
the peripheral area comprises a first bezel area located on a side of the display area in a second direction, the second direction intersecting with the first direction;
the first bezel area comprises at least one first area constant voltage power supply line provided on the base substrate; and
a constant voltage signal line connected by pixel circuits of at least one row of sub-pixels among the N rows of sub-pixels close to the arc-shaped display boundary is connected with the first area constant voltage power supply line of the first bezel area through a first adapter line.

2. The display substrate according to claim 1, wherein a constant voltage signal line connected by pixel circuits of a row of sub-pixels closest to the first bezel area among the N rows of sub-pixels close to the arc-shaped display boundary is connected with the first area constant voltage power supply line of the first bezel area through the first adapter line.

3. The display substrate according to claim 2, wherein the first adapter line comprises a first sub-connection line and a second sub-connection line, an extension direction of the first sub-connection line intersects with an extension direction of the second sub-connection line, and the first sub-connection line and the second sub-connection line are connected; and
the constant voltage signal line connected by the pixel circuits of the row of sub-pixels closest to the first bezel area among the N rows of sub-pixels close to the arc-shaped display boundary is connected with the first sub-connection line, and the second sub-connection line is connected with the first area constant voltage power supply line located in the first bezel area.

4. The display substrate according to claim 1, wherein constant voltage signal lines transmitting a same signal and connected by pixel circuits of K rows of sub-pixels among the N rows of sub-pixels close to the arc-shaped display boundary are connected together and connected with the first area constant voltage power supply line of the first bezel area through the first adapter line, where K is a positive integer less than or equal to N and greater than or equal to 2.

5. The display substrate according to claim 4, wherein K is less than N, and the K rows of sub-pixels are located on a side of remaining rows of sub-pixels of the N rows of sub-pixels close to the first bezel area.

6. The display substrate according to claim 5, wherein the K rows of sub-pixels comprise seven rows of sub-pixels closest to the first bezel area among the N rows of sub-pixels.

7. The display substrate according to claim 4, wherein the first adapter line comprises a first sub-connection line and a second sub-connection line, an extension direction of the first sub-connection line intersects with an extension direction of the second sub-connection line, and the first sub-connection line and the second sub-connection line are connected; and
constant voltage signal lines transmitting a same signal and connected by pixel circuits of adjacent rows of sub-pixels among the K rows of sub-pixels are electrically connected through a series connection line, a constant voltage signal line connected by pixel circuits of a row of sub-pixels closest to the first bezel area among the K rows of sub-pixels is connected with the first sub-connection line, and the second sub-connection line is connected with the first area constant voltage power supply line located in the first bezel area.

8. The display substrate according to claim 7, wherein series connection lines connected by the constant voltage signal lines connected by the pixel circuits of adjacent rows of sub-pixels among the K rows of sub-pixels extend in a stepped shape formed by the adjacent rows of sub-pixels.

9. The display substrate according to claim 7, wherein the series connection line is located on a side of the constant voltage signal line connected therewith away from the base substrate.

10. The display substrate according to claim 3, wherein the first sub-connection line and the second sub-connection line are located on a side of the first area constant voltage power supply line connected therewith away from the base substrate; and
the second sub-connection line is located on a side of the first sub-connection line away from the base substrate, or the second sub-connection line and the first sub-connection line are of an interconnected integral structure.

11. The display substrate according to claim 3, wherein the first bezel area further comprises a plurality of electrostatic discharge circuits, each of which is connected with a signal line and configured to discharge static electricity from the signal line connected therewith; and the second sub-connection line is located on a side of the plurality of electrostatic discharge circuits away from an edge of the display substrate in the first direction.

12. The display substrate according to claim 1, wherein the peripheral area further comprises a second bezel area located on at least one side of the display area in the first direction;
the second bezel area comprises at least one second area constant voltage power supply line provided on the base substrate;
the second area constant voltage power supply line is connected with the first area constant voltage power supply line; and
the constant voltage signal line connected by the pixel circuits of the at least one row of sub-pixels among the M rows of sub-pixels is electrically connected with the second area constant voltage power supply line through a second adapter line.

13. The display substrate according to claim 12, wherein the second bezel area further comprises at least one gate drive circuit provide on the base substrate; and the second area constant voltage power supply line is located on a side of the gate drive circuit close to the display area.

14. The display substrate according to claim 13, wherein an orthographic projection of the second area constant voltage power supply line on the base substrate is at least partially overlapped with an orthographic projection of the gate drive circuit on the base substrate.

15. The display substrate according to claim 1, wherein a plurality of constant voltage signal lines connected by pixel circuits of each row of sub-pixel circuits comprise a first initial signal line, a second initial signal line, and a third initial signal line;
the pixel circuit at least comprises a drive transistor, a first reset transistor, a second reset transistor, and a third reset transistor; a gate of the drive transistor is connected with a first node, a first electrode of the drive transistor is connected with a second node, and a second electrode of the drive transistor is connected with a third node; and the first reset transistor is connected with the third node and the first initial signal line, and configured to reset the third node using a first initial signal provided by the first initial signal line;
the second reset transistor is connected with the second initial signal line and an anode of the light emitting element, and configured to reset the anode of the light emitting element using a second initial signal provided by the second initial signal line;
the third reset transistor is connected with the second node and the third initial signal line, and configured to reset the second node using a third initial signal provided by the third initial signal line;
a plurality of first area constant voltage power supply lines provided in the first bezel area comprise a first initial power supply line, a second initial power supply line and a third initial power supply line;
the first initial signal line connected by the pixel circuits of the at least one row of sub-pixels among the N rows of sub-pixels close to the arc-shaped display boundary is connected with the first initial power supply line of the first bezel area;
the second initial signal line connected by the pixel circuits of the at least one row of sub-pixels among the N rows of sub-pixels close to the arc-shaped display boundary is connected with the second initial power supply line of the first bezel area;
the third initial signal line connected by the pixel circuits of the at least one row of sub-pixels among the N rows of sub-pixels close to the arc-shaped display boundary is connected with the third initial power supply line of the first bezel area; and
the first initial power supply line, the second initial power supply line, and the third initial power supply line are sequentially provided in a direction close to the display area.

16. The display substrate according to claim 15, wherein the peripheral area further comprises a second bezel area located on a side of the display area in the first direction, and the second bezel area is in communication with the first bezel area;
the second bezel area comprises a plurality of second area constant voltage power supply lines, and the plurality of second area constant voltage power supply lines comprise a fourth initial power supply line, a fifth initial power supply line and a sixth initial power supply line;
the fourth initial power supply line is connected with the first initial power supply line, the fifth initial power supply line is connected with the second initial power supply line, and the sixth initial power supply line is connected with the third initial power supply line; and
the fourth initial power supply line, the fifth initial power supply line, and the sixth initial power supply line are sequentially provided in the direction close to the display area.

17. The display substrate according to claim 1, wherein in a direction perpendicular to the display substrate, the display substrate comprises a first semiconductor layer, a first conductive layer, a second conductive layer, a second semiconductor layer, a third conductive layer, a fourth conductive layer, and a fifth conductive layer provided on the base substrate;
the constant voltage signal line is located on the third conductive layer; and
the at least one first area constant voltage power supply line is located on the first conductive layer, or located on the second conductive layer, or is a double-layer trace located on the first conductive layer and the second conductive layer.

18. A display apparatus, comprising a display substrate according to claim 1.

19. A display substrate, comprising a display area and a peripheral area surrounding the display area, wherein the display area comprises at least one segment of an arc-shaped display boundary;
the display area comprises M rows of sub-pixels provided on a base substrate, at least one row of sub-pixels among the M rows of sub-pixels comprise a plurality of sub-pixels arranged sequentially in a first direction, at least one sub-pixel among the plurality of sub-pixels comprises a pixel circuit and a light emitting element connected with the pixel circuit, and pixel circuits of the at least one row of sub-pixels among the M rows of sub-pixels are connected with at least one constant voltage signal line extending in the first direction; and N rows of sub-pixels close to the arc-shaped display boundary are arranged in a stepped manner, where both N and M are positive integers, and N is less than or equal to M;
the peripheral area comprises a first bezel area located on a side of the display area in a second direction and a first corner area located at a perimeter of the arc-shaped display boundary, and the first bezel area is in communication with the first corner area; and he second direction intersects with the first direction;
the first bezel area comprises at least one first area constant voltage power supply line provided on the base substrate; and
a constant voltage signal line connected by pixel circuits of at least one row of sub-pixels among the N rows of sub-pixels close to the arc-shaped display boundary is connected with the first area constant voltage power supply line of the first bezel area through a first adapter line; and a portion of the first adapter line is located in the first corner area.

20. The display substrate according to claim 19, wherein the first adapter line comprises a first sub-connection line and a second sub-connection line, the first sub-connection line and the second sub-connection line are connected, and an extension direction of the first sub-connection line intersects with an extension direction of the second sub-connection line; and the first sub-connection line is connected with a constant voltage signal line connected with a pixel circuit of at least one row of sub-pixels in N rows of sub-pixels close to the arc-shaped display boundary, and the second sub-connection line is connected with the first area constant voltage power supply line;
a connection position of the first sub-connection line and the second sub-connection line is located in the first corner area;
the peripheral area further comprises at least one second area constant voltage power supply line extending to the first corner area and connected with the first area constant voltage power supply line through the second sub-connection line;
the second area constant voltage power supply line and the second sub-connection line connected therewith are of an interconnected integral structure;
the first corner area further comprises a plurality of cascaded drive units provided on the base substrate, the second area constant voltage power supply line is located on a side of the plurality of cascaded drive units close to the display area, and the second sub-connection line is located on a side of the plurality of drive units close to the first area constant voltage power supply line in the first direction; and
the drive units are connected with a gate line connected by at least one row of sub-pixels through a drive connection line, and the drive connection line is located on a side of the first sub-connection line close to the display area in the second direction.

21-24. (canceled)
